(19) United States
(12) Patent Application Publication
(10) Pub. No.: US 2024/0292658 A1
(43) Pub. Date: Aug. 29, 2024

(54) DISPLAY DEVICE AND METHOD FOR FABRICATING THE SAME

(71) Applicant: Samsung Display Co., Ltd., Yongin-Si (KR)

(72) Inventors: Jung Hoon LEE, Yongin-si (KR); Jong Beom KO, Yongin-si (KR); Yeon Hong KIM, Yongin-si (KR); Eun Hyun KIM, Yongin-si (KR); Sun Hee LEE, Yongin-si (KR); Hyun Mo LEE, Yongin-si (KR)

(21) Appl. No.: 18/383,899

(22) Filed: Oct. 26, 2023

(30) Foreign Application Priority Data
Feb. 23, 2023 (KR) 10-2023-0023990

(51) Int. Cl. H10K 59/121; H10K 59/12

(52) U.S. Cl. CPC H10K 59/1213; H10K 59/1201

(57) ABSTRACT

The present disclosure relates to a display device, more particularly, to a display device in which the number of contact holes may be reduced to improve space utilization of pixels, and the method for fabricating the same. According to an embodiment of the disclosure, the display device includes a first active layer, a first transistor connected to the first active layer, a pixel electrode connected to the first transistor, a second active layer including a material different from a material of the first active layer, and a second transistor connected to the second active layer. At least a portion of the second active layer is directly connected to at least a portion of the first active layer.

### CROSS-REFERENCE TO RELATED APPLICATION

This application claims priority from Korean Patent Application No. 10-2023-0023990 filed on Feb. 23, 2023 in the Korean Intellectual Property Office, the disclosure of which is incorporated herein by reference in its entirety.

### BACKGROUND

### 1. Field of the Disclosure

The present disclosure relates to a display device, more particularly, to a display device in which the number of contact holes may be reduced to improve space utilization of pixels, and the method for fabricating the same.

### 2. Description of the Related Art

An organic light-emitting display apparatus includes display elements having luminance varying depending on electric current, for example, organic light-emitting diodes.

### SUMMARY

Aspects of the present disclosure provide a display device capable of improving pixel space utilization by reducing the number of contact holes, and a method of fabricating the same.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the disclosure, a display device comprises a first active layer, a first transistor connected to the first active layer, a pixel electrode connected to the first transistor, a second active layer including a material different from a material of the first active layer, and a second transistor connected to the second active layer. At least a portion of the second active layer is directly connected to at least a portion of the first active layer.

In an embodiment, the first active layer and the second active layer are disposed on a same layer.

In an embodiment, the at least a portion of the second active layer is in direct contact with the at least a portion of the first active layer.

In an embodiment, the at least a portion of the second active layer is disposed on the first active layer.

In an embodiment, the at least a portion of the second active layer overlaps the first active layer.

In an embodiment, the first active layer includes an extension portion extending toward the second active layer, and the at least a portion of the second active layer is directly connected to the extension portion of the first active layer.

In an embodiment, an insulating layer is not disposed on an interface between the first active layer and the second active layer.

In an embodiment, the first active layer includes indium-gallium-zinc oxide.

In an embodiment, the second active layer includes indium-gallium-zinc-tin oxide.

In an embodiment, the first transistor is a driving transistor and the second transistor is a switching transistor.

In an embodiment, a power line is connected to the second transistor.

In an embodiment, the power line overlaps an interface between the first active layer and the second active layer.

In an embodiment, the power line is any one of a first driving voltage line, a reference voltage line and an initialization voltage line.

According to an embodiment of the disclosure, a display device comprises a first active layer, a first transistor including a first gate electrode overlapping the first active layer, a second active layer including a material different from a material of the first active layer, a second transistor including a second gate electrode overlapping the second active layer, and a pixel electrode connected to the first transistor. At least a portion of the second active layer is directly connected to at least a portion of the first active layer.

In an embodiment, the first active layer and the second active layer are disposed on a same layer.

In an embodiment, the at least a portion of the second active layer is in direct contact with the at least a portion of the first active layer.

In an embodiment, the at least a portion of the second active layer is disposed on the first active layer.

In an embodiment, the at least a portion of the second active layer overlaps the first active layer.

According to an embodiment of the disclosure, a method of fabricating a display device is presented. The method comprises forming a first active layer on a substrate, forming a second active layer including a material different from a material of the first active layer on the substrate. At least a portion of the second active layer is directly connected to at least a portion of the first active layer. A first gate electrode of the first transistor is formed on the first active layer. A second gate electrode of the second transistor is formed on the second active layer.

In an embodiment, the first active layer and the second active layer are disposed on a same layer.

In an embodiment, the at least a portion of the second active layer is in direct contact with the at least a portion of the first active layer.

According to an embodiment of the present disclosure, as a first active layer and a second active layer including different materials are directly connected to each other, there is no need for separate contact holes and active connection electrodes to connect the first active layer and the second active layer. Accordingly, the pixel space utilization may be improved.

In addition, generation of parasitic capacitors between heterogeneous active layers and active connection electrodes for connecting the heterogeneous active layers can be suppressed.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail embodiments thereof with reference to the attached drawings.

FIG. 1 is a perspective view showing a display device according to an embodiment of the present disclosure.

FIG. 2 is a cross-sectional view showing a display device according to an embodiment of the present disclosure.

FIG. 3 is a plan view showing a display unit of a display device according to an embodiment of the present disclosure.

FIG. 4 is a block diagram illustrating a display panel and a display driver according to an embodiment.

FIG. 5 is a circuit diagram of a pixel of a display device according to an embodiment of the present disclosure.

FIG. 6 is a plan view of a pixel array of a display device including the pixel circuit of FIG. 5 according to an embodiment.

FIG. 7 is a plan view selectively showing only a first conductive layer among the elements of FIG. 6.

FIG. 8 is a plan view selectively showing only a second conductive layer among the elements of FIG. 6.

FIG. 9 is a plan view selectively showing only a third conductive layer among the elements of FIG. 6.

FIG. 10 is a plan view selectively showing only a fourth conductive layer among the elements of FIG. 6.

FIG. 11 is a plan view selectively showing only a fifth conductive layer among the elements of FIG. 6.

FIG. 12 is a plan view selectively showing only second to fourth conductive layers among the elements of FIG. 6.

FIG. 13 is a plan view selectively showing only second and third conductive layers among the elements of FIG. 6.

FIG. 14 is a cross-sectional view taken along line I-I′ of FIG. 6.

FIG. 15 is a cross-sectional view taken along line II-II′ of FIG. 6.

FIG. 16 is a cross-sectional view showing a structure of a display device according to an embodiment of the present disclosure.

FIGS. 17, 18, 19, and 20 are cross-sectional views showing structures of a pixel of a display device according to an embodiment of the present disclosure.

FIG. 21 is a cross-sectional view showing an example of an organic light-emitting diode of FIG. 19.

FIG. 22 is a cross-sectional view showing an example of an organic light-emitting diode of FIG. 20.

FIG. 23 is a cross-sectional view showing a structure of a pixel of a display device according to an embodiment of the present disclosure.

FIGS. 24, 25, 26, 27, 28, 29, 30, 31, 32, 33, 34, 35, and 36 are cross-sectional views showing processing steps for illustrating a method of fabricating a display device according to an embodiment of the present disclosure.

FIG. 37 is a plan view of a pixel array of a display device including the pixel circuits of FIG. 5 according to the embodiment.

FIG. 38 is a cross-sectional view taken along line I-I′ of FIG. 37.

### DETAILED DESCRIPTION OF THE EMBODIMENTS

Features of the present disclosure and methods to achieve them will become apparent from the descriptions of exemplary embodiments hereinbelow with reference to the accompanying drawings. However, the present disclosure is not limited to exemplary embodiments disclosed herein but may be implemented in various different ways. The exemplary embodiments are provided for making the disclosure of the present disclosure thorough and for fully conveying the scope of the present disclosure to those skilled in the art. It is to be noted that the scope of the present disclosure is defined only by the claims.

As used herein, a phrase “an element A on an element B” refers to that the element A may be disposed directly on the element B and/or the element A may be disposed indirectly on the element B via another element C. Like reference numerals denote like elements throughout the descriptions. The figures, dimensions, ratios, angles, numbers of elements given in the drawings are merely illustrative and are not limiting.

Although terms such as first, second, etc. are used to distinguish arbitrarily between the elements such terms describe, and thus these terms are not necessarily intended to indicate temporal or other prioritization of such elements. These terms are used to merely distinguish one element from another. Accordingly, as used herein, a first element may be a second element within the technical scope of the present disclosure.

Features of various exemplary embodiments of the present disclosure may be combined partially or totally. As will be clearly appreciated by those skilled in the art, technically various interactions and operations are possible. Various exemplary embodiments can be practiced individually or in combination.

Hereinafter, exemplary embodiments of the present disclosure will be described with reference to the accompanying drawings.

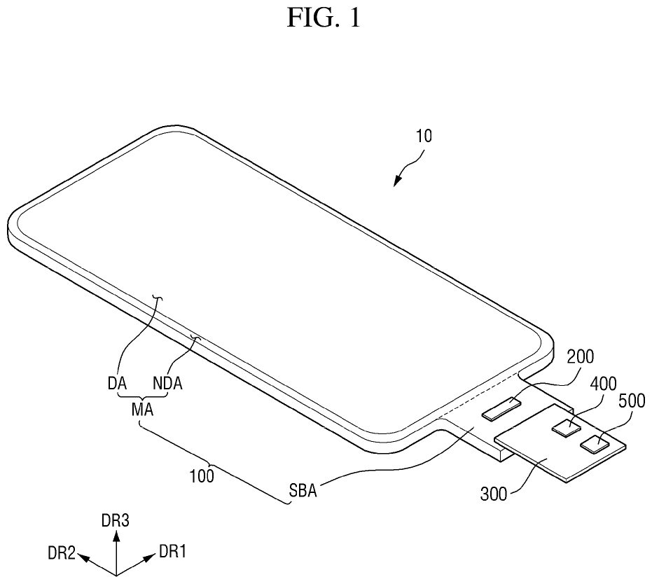

FIG. 1 is a perspective view showing a display device 10 according to an embodiment of the present disclosure.

Referring to FIG. 1, the display device 10 may be employed by portable electronic devices such as a mobile phone, a smart phone, a tablet PC, a mobile communications terminal, an electronic notebook, an electronic book, a portable multimedia player (PMP), a navigation device and an ultra mobile PC (UMPC). For example, the display device 10 may be used as a display unit of a television, a laptop computer, a monitor, an electronic billboard, or the Internet of Things (IOT). For another example, the display device 10 may be applied to wearable devices such as a smart watch, a watch phone, a glasses-type display, and a head-mounted display (HMD) device.

The display device 10 may have a shape similarly to a quadrangular shape when viewed from the top. For example, the display device 10 may have a shape similar to a rectangle having shorter sides in a first direction DR1 and longer sides in a second direction DR2. The corners where the shorter sides in the first direction DR1 meet the longer sides in the second direction DR2 may be rounded with a predetermined curvature or may be a right angle. The shape of the display device 10 when viewed from the top is not limited to a quadrangular shape, but may be formed in a shape similar to other polygonal shapes, a circular shape, or an elliptical shape.

The display device 10 may include a display panel 100, a display driver 200, a circuit board 300, a touch driver 400, and a power supply unit 500.

The display panel 100 may include a main area MA and a subsidiary area SBA.

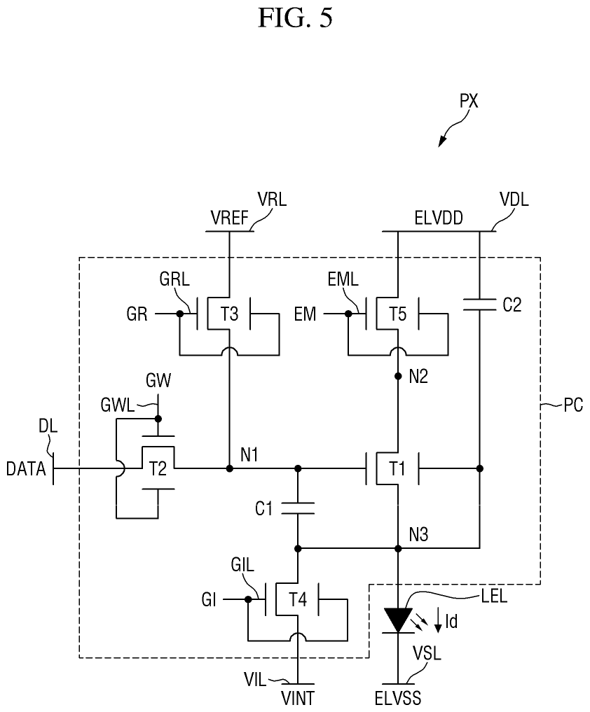

The main area MA may include a display area DA having pixels for displaying images, and a non-display area NDA located around the display area DA. The display area DA may emit light from a plurality of emission areas or a plurality of opening areas. For example, the display panel 100 may include a pixel circuit PC, e.g., see FIG. 5, including switching elements, a pixel-defining layer that defines the emission areas or the opening areas, and a self-light-emitting element.

For example, the self-light-emitting element may include, but is not limited to, at least one of: an organic light-emitting diode including an organic emissive layer, a quantum-dot light-emitting diode (quantum LED) including a quantum-dot emissive layer, an inorganic light-emitting diode (inorganic LED) including an inorganic semiconductor, and a micro light-emitting diode (micro LED).

The non-display area NDA may be disposed on the outer side of the display area DA. The non-display area NDA may be defined as the edge area of the main area MA of the display panel 100. The non-display area NDA may include a gate driver (not shown) that applies gate signals to gate lines, and fan-out lines (not shown) that connect the display driver 200 with the display area DA.

The subsidiary area SBA may extend from one side of the main area MA. The subsidiary area SBA may include a flexible material that can be bent, folded, or rolled. For example, when the subsidiary area SBA is bent, the subsidiary area SBA may overlap with the main area MA in the thickness direction, e.g., in a third direction DR3. The subsidiary area SBA may include pads connected to the display driver 200 and the circuit board 300. Optionally, the subsidiary area SBA may be eliminated, and the display driver 200 and the pads may be disposed in the non-display area NDA.

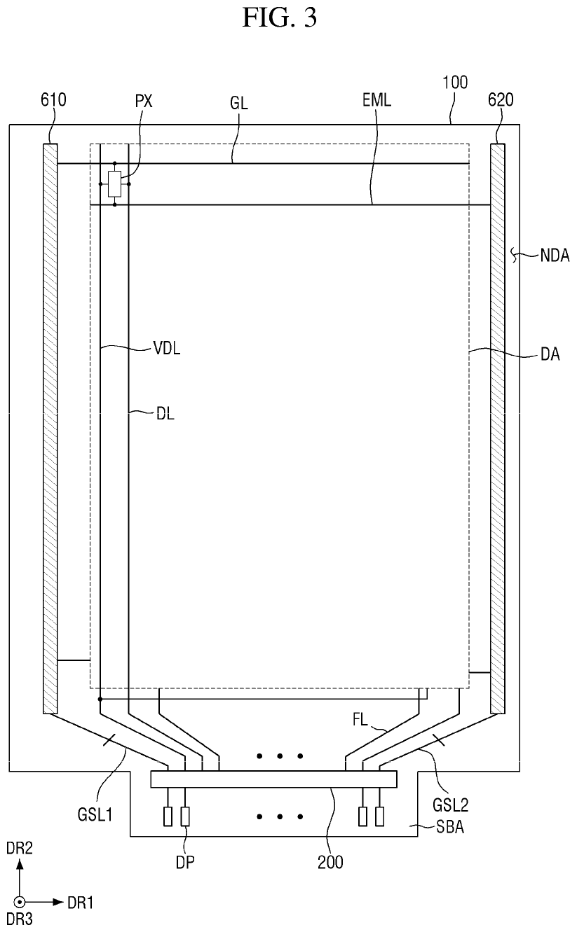

The display driver 200 may output signals and voltages for driving the display panel 100. The display driver 200 may supply data voltages to data lines DL, e.g., see FIGS. 3-5. The display driver 200 may apply a power voltage to the power line and may supply gate control signals to the gate driver. The display driver 200 may be implemented as an integrated circuit (IC) and may be attached on the display panel 100 by a chip-on-glass (COG) technique, a chip-on-plastic (COP) technique, or ultrasonic bonding. For example, the display driver 200 may be disposed in the subsidiary area SBA and may overlap with the main area MA in the thickness direction, i.e., in the third direction DR3, as the subsidiary area SBA is bent. For another example, the display driver 200 may be mounted on the circuit board 300.

The circuit board 300 may be attached on the pads of the display panel 100 using an anisotropic conductive film (ACF). Lead lines of the circuit board 300 may be electrically connected to the pads of the display panel 100. The circuit board 300 may be a flexible printed circuit board (FPCB), a printed circuit board (PCB), or a flexible film such as a chip-on-film (COF).

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense a change in the capacitance between the plurality of touch electrodes. For example, the touch driving signal may be a pulse signal having a predetermined frequency. The touch driver 400 may determine whether there is an input and may find the coordinates of the input based on the amount of the change in the capacitance between the touch electrodes. The touch driver 400 may be implemented as an integrated circuit (IC).

The power supply unit 500 may be disposed on the circuit board 300 to apply a supply voltage to the display driver 200 and the display panel 100. The power supply unit 500 may generate a first driving voltage to provide it to a first driving voltage line VDL, e.g., see FIG. 5, may generate initialization voltages to provide them to initialization voltage lines VIL, e.g., see FIG. 5, and may generate a common voltage to provide it to a common electrode common to light-emitting elements of a plurality of pixels. For example, the first driving voltage may be a high-level voltage for driving the light-emitting element, and the common voltage and a second driving voltage may be a low-level voltage for driving the light-emitting element.

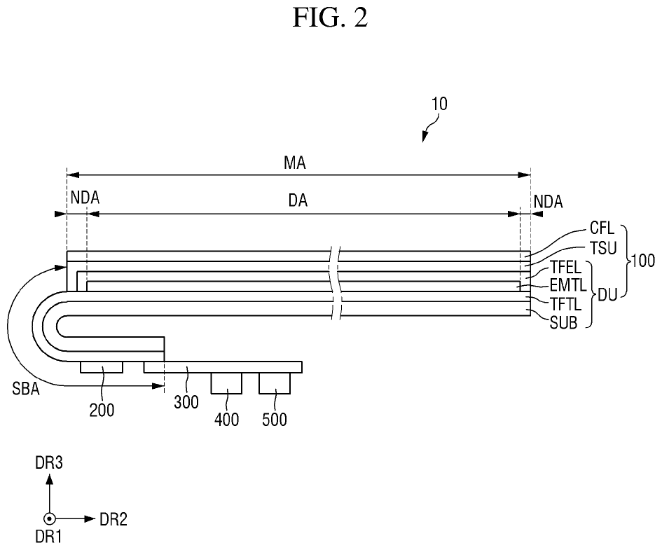

FIG. 2 is a cross-sectional view showing the display device 10 according to an embodiment of the present disclosure.

Referring to FIG. 2, the display panel 100 may include a display unit DU, a touch sensing unit TSU, and a color filter layer CFL. The display unit DU may include a substrate SUB, a thin-film transistor layer TFTL, a light-emitting layer EMTL and an encapsulation layer TFEL.

The substrate SUB may be a base substrate or a base member. The substrate SUB may be a flexible substrate that can be bent, folded, or rolled. For example, the substrate SUB may include, but is not limited to, a polymer resin such as polyimide (PI). For another example, the substrate SUB may include a glass material or a metal material.

The thin-film transistor layer TFTL may be disposed on the substrate SUB. The thin-film transistor layer TFTL may include a plurality of thin-film transistors forming pixel circuits PC of pixels. The thin-film transistor layer TFTL may include gate lines, data lines DL, power lines, gate control lines, fan-out lines for connecting the display driver 200 with the data lines DL, lead lines for connecting the display driver 200 with the pads, etc. Each of the thin-film transistors may include a semiconductor region, a source electrode, a drain electrode, and a gate electrode. For example, when the gate driver is formed on one side of the non-display area NDA of the display panel 100, the gate driver may include thin-film transistors.

The thin-film transistor layer TFTL may be disposed in the display area DA, the non-display area NDA and the subsidiary area SBA. The thin-film transistors in each of the pixels, the gate lines, the data lines DL and the power lines in the thin-film transistor layer TFTL may be disposed in the display area DA. The gate control lines and the fan-out lines in the thin-film transistor layer TFTL may be disposed in the non-display area NDA. The lead lines of the thin-film transistor layer TFTL may be disposed in the subsidiary area SBA.

The light-emitting element layer EMTL may be disposed on the thin-film transistor layer TFTL. The light-emitting element layer EMTL may include a plurality of light-emitting elements in each of which a pixel electrode, an emissive layer and a common electrode are stacked on one another sequentially to emit light, and a pixel-defining layer for defining the pixels. The plurality of light-emitting elements in the light-emitting element layer may be disposed in the display area DA.

For example, the emissive layer may be an organic emissive layer containing an organic material. The emissive layer may include a hole transporting layer, an organic light-emitting layer and an electron transporting layer. When the pixel electrode receives a voltage and the common electrode receives a cathode voltage through the thin-film transistors in the thin-film transistor layer TFTL, the holes and electrons may move to the organic light-emitting layer through the hole transporting layer and the electron transporting layer, respectively, such that they combine in the organic light-emitting layer to emit light. For example, the pixel electrode may be an anode electrode while the common electrode may be a cathode electrode. It is, however, to be understood that the present disclosure is not limited thereto.

As another example, the light-emitting elements may include quantum-dot light-emitting diodes each including a quantum-dot emissive layer, inorganic light-emitting diodes each including an inorganic semiconductor, or micro light-emitting diodes.

The encapsulation layer TFEL may cover the upper and side surfaces of the light-emitting element layer EMTL, and can protect the light-emitting element layer EMTL. The encapsulation layer TFEL may include at least one inorganic layer and at least one organic layer for encapsulating the light-emitting element layer EMTL.

The touch sensing unit TSU may be disposed on the encapsulation layer TFEL. The touch sensing unit TSU may include a plurality of touch electrodes for sensing a user's touch by capacitive sensing, and touch lines connecting the plurality of touch electrodes with the touch driver 400. For example, the touch sensing unit TSU may sense a user's touch by mutual capacitance sensing or self-capacitance sensing.

For another example, the touch sensing unit TSU may be disposed on a separate substrate disposed on the display unit DU. In such case, the substrate supporting the touch sensing unit TSU may be a base member encapsulating the display unit DU.

The plurality of touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters associated with the plurality of emission areas, respectively. Each of the color filters may selectively transmit light of a particular wavelength and block or absorb lights of other wavelengths. The color filter layer CFL may absorb some of lights introduced from the outside of the display device 10 to reduce the reflection of external light. Accordingly, the color filter layer CFL can prevent distortion of colors due to the reflection of external light.

Since the color filter layer CFL is disposed directly on the touch sensing unit TSU, the display device 10 may require no separate substrate for the color filter layer CFL. Therefore, the thickness of the display device 10 can be relatively reduced.

The subsidiary area SBA of the display panel 100 may extend from one side of the main area MA. The subsidiary area SUB may include a flexible material that can be bent, folded, or rolled. For example, when the subsidiary area SBA is bent, the subsidiary area SBA may overlap with the main area MA in the thickness direction, i.e., in the third direction DR3. The subsidiary area SBA may include pads electrically connected to the display driver 200 and the circuit board 300.

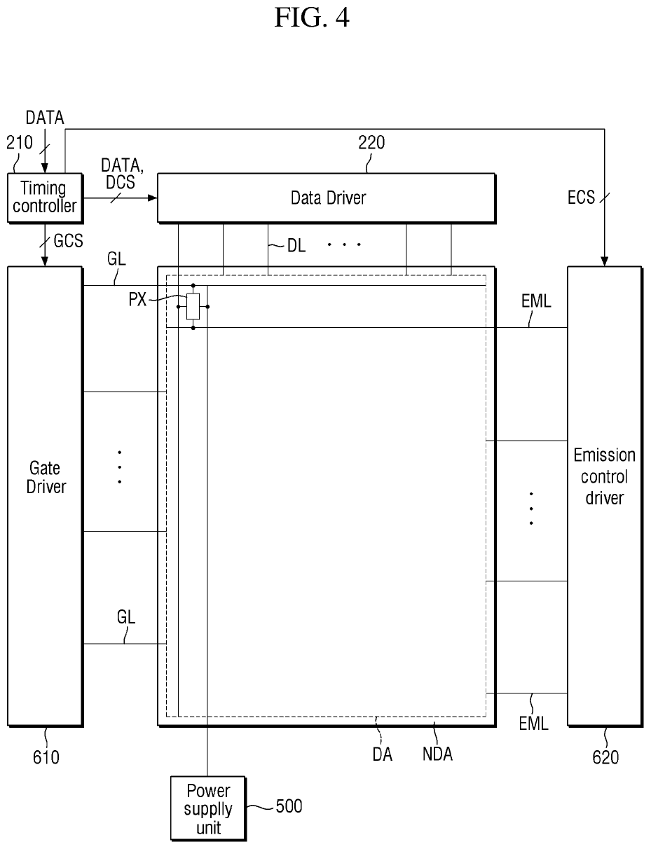

FIG. 3 is a plan view showing a display unit of a display device according to an embodiment of the present disclosure. FIG. 4 is a block diagram illustrating a display panel and a display driver according to an embodiment.

Referring to FIGS. 3 and 4, the display panel 100 may include the display area DA and the non-display area NDA.

The display area DA may include a plurality of pixels PX, a plurality of first driving voltage lines VDL connected to the plurality of pixels PX, a plurality of gate lines GL, a plurality of second driving voltage lines VSL, e.g., see FIG. 5, a plurality of emission control lines EML, and a plurality of data lines DL.

Each of the plurality of pixels PX may be connected to a gate line GL, a data line DL, an emission control line EML, a first driving voltage line VDL, and a second driving voltage line VSL. Each of the plurality of pixels PX may include at least one transistor, a light-emitting element, and a capacitor.

The gate lines GL may extend in the first direction DR1 and may be spaced apart from one another in the second direction DR2 intersecting the first direction DR1. The gate lines GL may be arranged along the second direction DR2. The gate lines GL may sequentially supply gate signals to the plurality of pixels PX.

The emission control lines EML may extend in the first direction DR1 and may be spaced apart from one another in the second direction DR2. The emission control lines EML may be arranged along the second direction DR2. The emission control lines EML may sequentially supply an emission control signal to the plurality of pixels PX.

The data lines DL may extend in the second direction DR2 and may be spaced apart from one another in the first direction DR1. The data lines DL may be arranged along the first direction DR1. The data lines DL may supply data voltages to the plurality of pixels PX. The data voltage may determine the luminance of each of the plurality of pixels PX.

The first driving voltage lines VDL may extend in the second direction DR2 and may be spaced apart from one another in the first direction DR1. The first driving voltage lines VDL may be arranged along the first direction DR1. The first driving voltage lines VDL may supply the first driving voltage to the plurality of pixels PX. The first driving voltage may be a high-level voltage for driving light-emitting elements of the pixels PX.

The non-display area NDA may surround the display area DA. The non-display area NDA may include a gate driver 610, an emission control driver 620, fan-out lines FL, a first gate control line GSL1 and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The subsidiary area SBA may extend from one side of the non-display area NDA. The subsidiary area SBA may include the display driver 200 and pads DP. The pads DP may be disposed closer to one edge of the subsidiary area SBA than the display driver 200. The pads DP may be electrically connected to the circuit board 300 through an anisotropic conductive film ACF. The display driver 200 may include a timing controller 210 and a data driver 220.

The timing controller 210 may receive digital video data DATA and timing signals from the circuit board 300. The timing controller 210 may generate a data control signal DCS to control the operation timing of the data driver 220, may generate the gate control signal GCS to control the operation timing of the gate driver 610, and may generate the emission control signal ECS to control the operation timing of the emission control driver 620 based on the timing signals. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and may supply them to the data lines DL through the fan-out lines FL. The gate signals from the gate driver 610 may be used to select pixels PX to which a data voltage is applied, and the selected pixels PX may receive the data voltage through the data lines DL.

The power supply unit 500 may be disposed on the circuit board 300 to supply a power voltage to the display driver 200 and the display panel 100. The power supply unit 500 may generate a first driving voltage to supply it to a first driving voltage line VDL, may generate an initialization voltage to supply it to initialization voltage lines VIL, e.g., see FIG. 5, and may generate a common voltage to supply it to a common electrode shared by the light-emitting elements of a plurality of pixels.

The gate driver 610 may be disposed on one outer side of the display area DA or on one outer side of the non-display area NDA, and the emission control driver 620 may be disposed on the opposite outer side of the display area DA or on the opposite outer side of the non-display area NDA. It should be understood, however, that the present disclosure is not limited thereto. For another example, the gate driver 610 and the emission control driver 620 may be disposed on one side or the opposite side of the non-display area NDA.

The gate driver 610 may include a plurality of transistors for generating gate signals based on the gate control signal GCS. The emission control driver 620 may include a plurality of transistors for generating emission control signals based on the emission control signal ECS. For example, the transistors of the gate driver 610 and the transistors of the emission control driver 620 may be formed on the same layer as the transistors of each of the pixels PX. The gate driver 610 may provide gate signals to the gate lines GL, and the emission control driver 620 may provide emission control signals to the emission control lines EML.

FIG. 5 is a circuit diagram of a pixel PX of a display device according to an embodiment of the present disclosure.

Referring to FIG. 5, the pixel PX may include a light-emitting element LEL, e.g., an organic light-emitting diode, as a display element and the pixel circuit PC connected to the light-emitting element LEL. The pixel circuit PC may include first to fifth transistors T1 to T5 and first and second capacitors C1 and C2. The first transistor T1 may be a driving transistor in which a size of a source-drain current is determined according to a gate-source voltage, and each of the second to fifth transistors T2 to T5 may be a switching transistor that is turned on/off according to the gate-source voltage, substantially a gate voltage. The first to fifth transistors T1 to T5 may be implemented as thin-film transistors. According to the type (p-type or n-type) and/or the operating condition of the transistor, the first electrode of each of the first to fifth transistors T1 to T5 may be a source electrode or a drain electrode, and the second electrode may be an electrode different from the first electrode. For example, when the first electrode is the source electrode, the second electrode may be the drain electrode.

The pixel PX may be connected to a first gate line GWL that transmits a first gate signal GW, a second gate line GIL that transmits a second gate signal GI, a third gate line GRL that transmits a third gate signal GR, an emission control line EML that transmits an emission control signal EM, and a data line DL that transmits a data signal DATA. The first driving voltage line VDL may transmit a first driving voltage ELVDD to the first transistor T1. The initialization voltage line VIL may transmit an initialization voltage VINT to the light-emitting element LEL, e.g., an organic light-emitting diode. A reference voltage line VRL may transmit a reference voltage VREF to the gate electrode of the first transistor T1. Meanwhile, depending on the pixel structure, the initialization voltage line VIL described above may include a plurality of initialization voltage lines VIL, e.g., a first initialization voltage line and a second initialization voltage line that transmit initialization voltages of different sizes.

The plurality of first to fifth transistors T1 to T5 may include an oxide semiconductor material. Since the oxide semiconductor has high carrier mobility and low leakage current, the voltage drop is not large although the driving time is long. That is, in the case of an oxide semiconductor, since a color change of an image due to a voltage drop is not large even during low-frequency driving, low-frequency driving is possible. Accordingly, a display device preventing the generation of leakage current and having reduced power consumption may be implemented by the plurality of first to fifth transistors T1 to T5 including an oxide semiconductor material. In addition, in the case of using an oxide semiconductor transistor, a crystallization process by excimer laser annealing (ELA) is not required to form a low-temperature polycrystalline silicon (LTPS) semiconductor transistor, and thus the manufacturing cost of the display panel 100 may be reduced, so that it is suitable for implementation of a large-area display device.

The oxide semiconductor is sensitive to light, so that a fluctuation in current amount and the like may occur due to light from the outside. Accordingly, it may be considered to absorb or reflect light from the outside by positioning a metal layer under the oxide semiconductor. The metal layer positioned below the oxide semiconductor of each of the first to fifth transistors T1 to T5 may function as a lower gate electrode, e.g., a counter gate electrode. That is, the first to fifth transistors T1 to T5 may be double gate transistors having two gate electrodes, e.g., a first gate electrode and a second gate electrode, or a gate electrode and a counter gate electrode. The first gate electrode and the second gate electrode may be disposed to face each other on different layers. For example, each of the first to fifth transistors T1 to T5 may be an N-channel oxide semiconductor transistor, and the first gate electrode and the second gate electrode of each of the first to fifth transistors T1 to T5 may be positioned to face each other with the oxide semiconductor interposed therebetween.

The first transistor T1 includes the first gate electrode connected to a first node N1 (or gate node), the second gate electrode connected to a third node N3, a first electrode connected to a second node N2, and a second electrode connected to the third node N3. The second gate electrode of the first transistor T1 may be connected to the second electrode of the first transistor T1 to be controlled by a voltage applied to the second electrode of the first transistor T1, and may improve the output saturation characteristics of the first transistor T1. The first electrode of the first transistor T1 may be connected to the first driving voltage line VDL via the fifth transistor T5, and the second electrode may be connected to the pixel electrode of the light-emitting element LEL. The first transistor T1 may serve as a driving transistor, and may control the magnitude, e.g., current amount, of a driving current Id flowing to the light-emitting element LEL by receiving the data signal DATA according to the switching operation of the second transistor T2.

The second transistor T2, e.g., data writing transistor, includes a first gate electrode and a second gate electrode connected to the first gate line GWL, a first electrode connected to the data line DL, and a second electrode connected to the first node N1 (or the gate electrode of the first transistor T1). The second transistor T2 may be turned on according to the first gate signal GW transmitted to the first gate line GWL to electrically connect the data line DL to the first node N1, and may transmit the data signal DATA transmitted to the data line DL to the first node N1.

The third transistor T3, e.g., a first initialization transistor, includes a first gate electrode and a second gate electrode connected to the third gate line GRL, a first electrode connected to the reference voltage line VRL, and a second electrode connected to the first node N1 (or the gate electrode of the first transistor T1). The third transistor T3 may be turned on according to the third gate signal GR transmitted to the third gate line GRL and transmit the reference voltage VREF transmitted to the reference voltage line VRL to the first node N1.

The fourth transistor T4, e.g., a second initialization transistor, includes a first gate electrode and a second gate electrode connected to the second gate line GIL, a first electrode connected to the third node N3 (or the second electrode of the first transistor T1), and a second electrode connected to the initialization voltage line VIL. The fourth transistor T4 may be turned on according to the second gate signal GI transmitted to the second gate line GIL and transmit the initialization voltage VINT transmitted to the initialization voltage line VIL to the third node N3.

The fifth transistor T5, e.g., a light-emitting control transistor, includes a first gate electrode and a second gate electrode connected to the emission control line EML, a first electrode connected to the first driving voltage line VDL, and a second electrode connected to the second node (or the first electrode of the first transistor T1). The fifth transistor T5 may be turned on or off according to the emission control signal EM transmitted to the emission control line EML.

A first capacitor C1 may be connected between the first node N1 and the third node N3. The first electrode of the first capacitor C1 may be connected to the gate electrode of the first transistor T1, and the second terminal thereof may be connected to the second gate electrode and the second electrode of the first transistor T1, the first electrode of the fourth transistor T4, and the pixel electrode, e.g., anode electrode, of the light-emitting element LEL. The first capacitor C1 may be a storage capacitor and may store a voltage corresponding to a threshold voltage and a data signal of the first transistor T1.

The second capacitor C2 may be connected between the third node N3 and the first driving voltage line VDL. The first electrode of the second capacitor C2 may be connected to the first driving voltage line VDL, and the second electrode thereof may be connected to the second gate electrode and the second electrode of the first transistor T1, the second electrode of the first capacitor C1, the first electrode of the fourth transistor T4, and the pixel electrode of the light-emitting element LEL. The capacitance of the first capacitor C1 may be greater than the capacitance of the second capacitor C2.

The light-emitting element LEL may include a pixel electrode, e.g., an anode electrode, and a counter electrode, e.g., a cathode electrode, facing the pixel electrode, and the counter electrode may be applied with a second driving voltage ELVSS. The counter electrode may be connected to the second driving voltage line VSL transmitting the second driving voltage ELVSS. The counter electrode may be a common electrode commonly shared by the plurality of pixels PX.

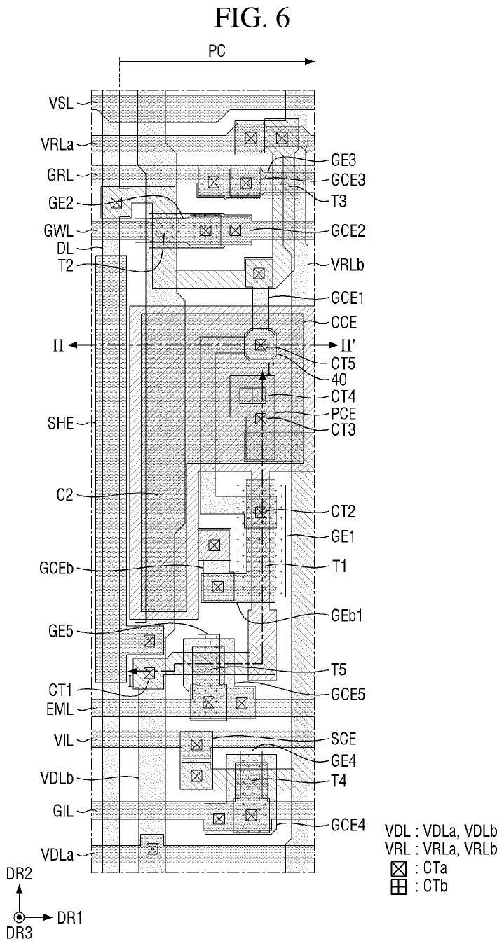

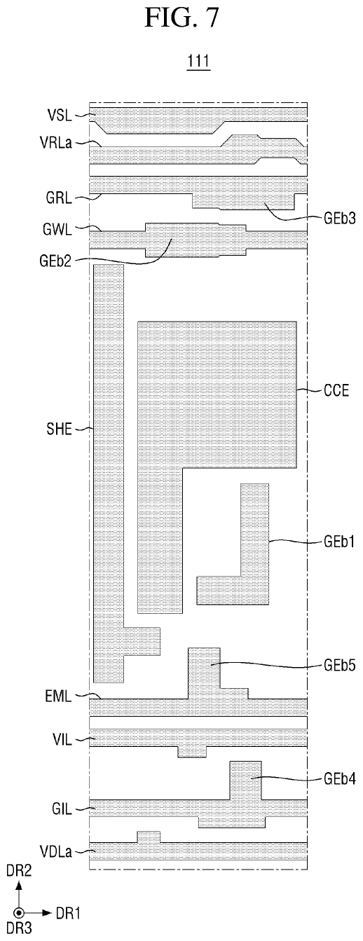

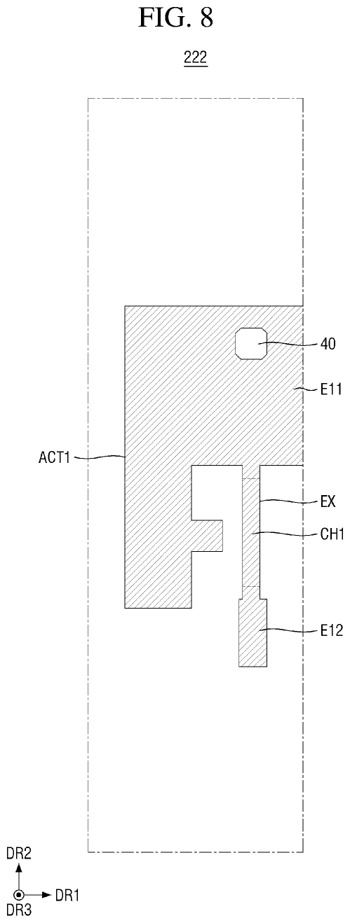

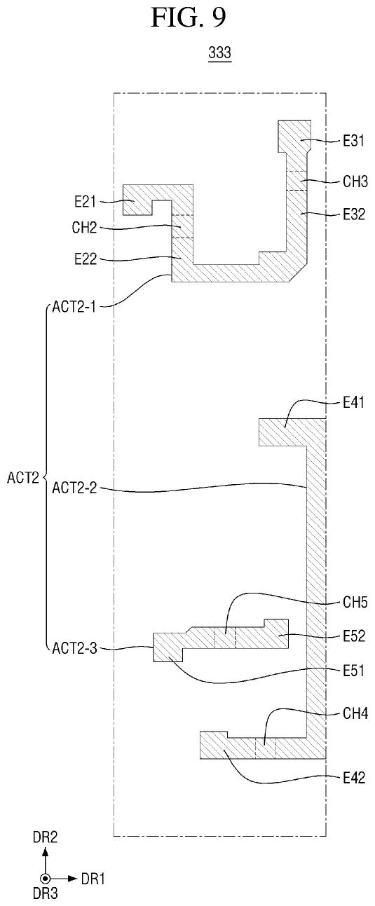

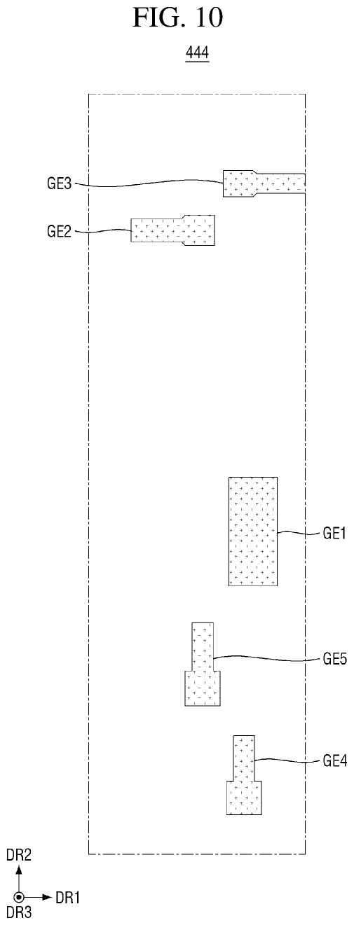

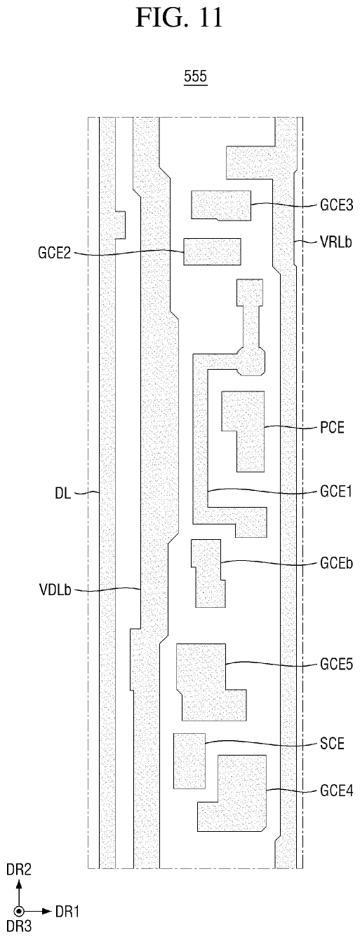

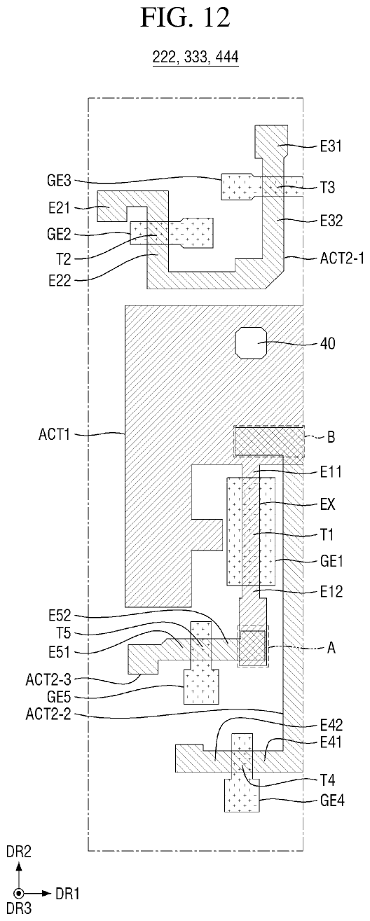

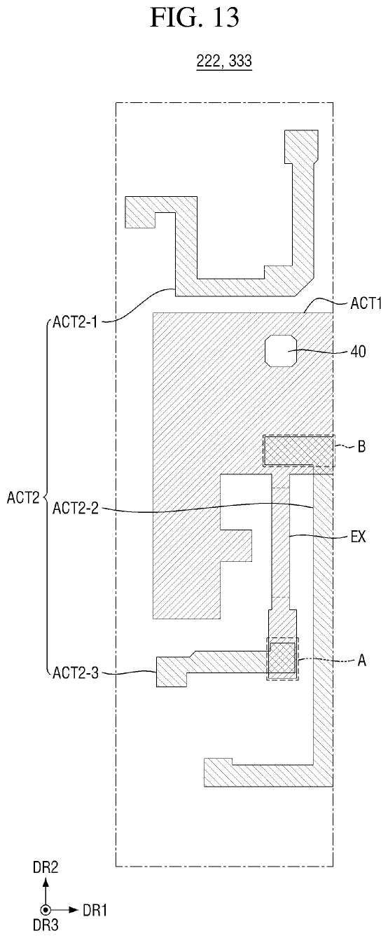

FIG. 6 is a plan view of a pixel array of a display device including the pixel circuit PC of FIG. 5 according to an embodiment. FIG. 7 is a plan view selectively showing only a first conductive layer 111 among the elements of FIG. 6. FIG. 8 is a plan view selectively showing only a second conductive layer 222 among the elements of FIG. 6. FIG. 9 is a plan view selectively showing only a third conductive layer 333 among the elements of FIG. 6. FIG. 10 is a plan view selectively showing only a fourth conductive layer 444 among the elements of FIG. 6. FIG. 11 is a plan view selectively showing only a fifth conductive layer 555 among the elements of FIG. 6. FIG. 12 is a plan view selectively showing only second to fourth conductive layers 222 to 444 among the elements of FIG. 6. FIG. 13 is a plan view selectively showing only second and third conductive layers 222 and 333 among the elements of FIG. 6.

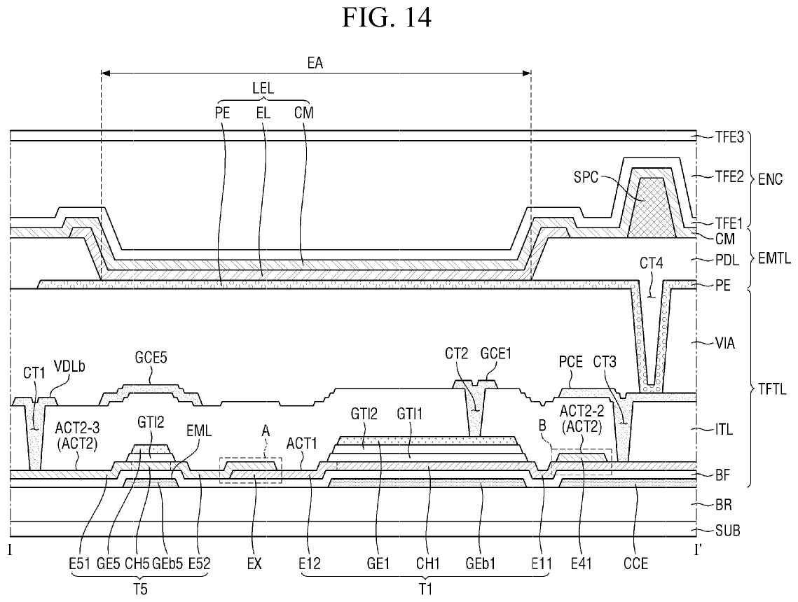

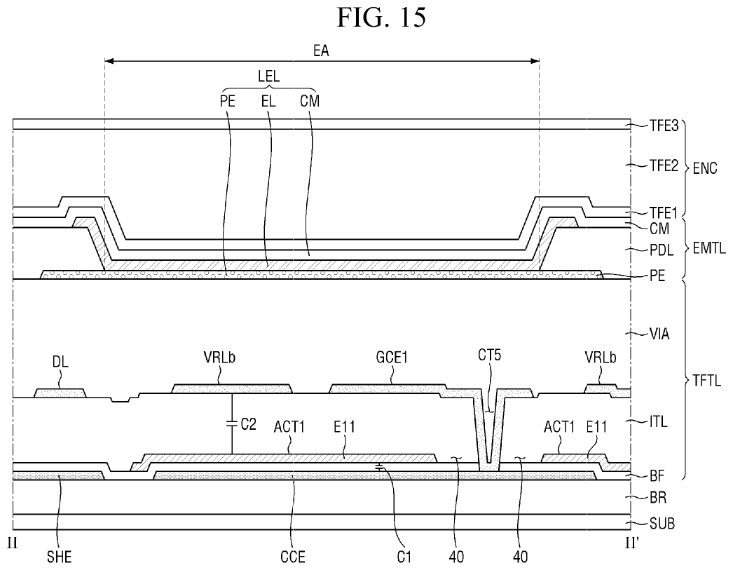

As shown in FIG. 6, contact holes may be divided into a first-type contact hole CTa, and a second-type contact hole CTb. The first-type contact hole CTa may connect the fourth conductive layer 444 to be described later with an underlying conductive layer, e.g., at least one of the first to fourth conductive layers 111 to 444. The second-type contact hole CTb may connect a sixth conductive layer, e.g., a pixel electrode PE as illustrated in FIGS. 14-15, with an underlying conductive layer, e.g., at least one of the first to fifth conductive layers 111 to 555.

The pixel of the display device 10 according to the embodiment of the present disclosure may include the pixel circuit PC as shown in FIG. 6, and the light-emitting element LEL, e.g., see FIG. 14, connected to the pixel circuit PC.

The pixel circuit PC may include, for example, first to fifth transistors T1 to T5, a first capacitor C1, and a second capacitor C2, e.g. see FIG. 15.

The pixel circuit PC may include, for example, the first to fifth transistors T1 to T5, the first capacitor C1 and the second capacitor C2 disposed in the region defined by being surrounded by two data lines DL adjacent in the first direction DR1, an upper reference voltage line VRLb, a lower reference voltage line VRLa, and the second gate line GIL.

The pixel circuit PC may include, for example, may be connected to the anode electrode, e.g., the pixel electrode, of the light-emitting element, the data line DL, the first gate line GWL, the second gate line GIL, the third gate line GRL, the emission control line EML, the first driving voltage line VDL, the reference voltage line VRL, and the initialization voltage line VIL.

The first conductive layer 111 may be disposed on the substrate along the third direction DR3. The first conductive layer 111, as shown in FIGS. 6 and 7, may include the second driving voltage line VSL, the lower reference voltage line VRLa, the third gate line GRL, the first gate line GWL, a shielding electrode SHE, the emission control line EML, the initialization voltage line VIL, the second gate line GIL, a capacitor electrode CCE, and a first counter gate electrode GEb1.

The first gate line GWL may extend in the first direction DR1. The first gate line GWL may include a second counter gate electrode GEb2 of the second transistor T2. For example, a portion of the first gate line GWL may be the second counter gate electrode GEb2.

The second gate line GIL may extend in the first direction DR1. The second gate line GIL may include a fourth counter gate electrode GEb4 of the fourth transistor T4. For example, a portion of the second gate line GIL may be the fourth counter gate electrode GEb4.

The third gate line GRL may extend in the first direction DR1. The third gate line GRL may include a third counter gate electrode GEb3 of the third transistor T3. For example, a portion of the third gate line GRL may be the third counter gate electrode GEb3.

The emission control line EML may extend in the first direction DR1. The emission control line EML may include a fifth counter gate electrode GEb5 of the fifth transistor T5. For example, a portion of the emission control line EML may be the fifth counter gate electrode GEb5.

The shielding electrode SHE may extend in the second direction DR2. In addition, a portion of the shielding electrode SHE may extend in the first direction DR1. The shielding electrode SHE may overlap the data line DL which will be described later. Since the data line DL is adjacent to a first capacitor, e.g., the capacitor electrode CCE and a first active layer ACT1, e.g., see FIG. 8, the voltage of the data line DL, e.g., the data voltage, may be modified by being coupled by the voltage of the first capacitor, e.g., the voltage of the capacitor electrode CCE and the first active layer ACT1. In other words, the data voltage of the data line DL may become unstable. The shielding electrode SHE overlaps the data line DL in the third direction DR3 to shield the data line DL and receives a positive voltage, e.g., the first driving voltage, thereby stabilizing the data voltage of the data line DL by minimizing the coupling between the voltage of the data line DL and the voltage of the first capacitor.

The initialization voltage line VIL may extend along the first direction DR1.

One side of the capacitor electrode CCE may extend toward the emission control line EML.

One side of the first counter gate electrode GEb1 may extend toward the capacitor electrode CCE, and the other side of the first counter gate electrode GEb1 may extend toward the capacitor electrode CCE.

The second conductive layer 222 may be disposed on the first conductive layer 111 along the third direction DR3. An insulating film may be disposed between the first conductive layer 111 and the second conductive layer 222. The second conductive layer 222 may include the first active layer ACT1 as shown in FIGS. 6, 8, 12 and 13.

The first active layer ACT1 may form the first transistor T1 along with the first gate electrode GE1 which will be described later. For example, as shown in FIGS. 8 and 12, the first active layer ACT1 may include a first electrode E11 of the first transistor T1, a second electrode E12 of the first transistor T1, and a first channel region CH1 of the first transistor T1. Here, the first electrode E11 of the first transistors T1 may be the one of a source electrode and a drain electrode of the first transistors T1, and the second electrode E12 of the first transistors T1 may be the other of the source electrode and the drain electrode of the first transistors T1.

The first active layer ACT1 may include an extension portion EX. Also, the first active layer ACT1 may have a hole 40 penetrating in the third direction DR3. Through this hole 40, the first conductive layer 111, e.g., the capacitor electrode CCE, disposed below the first active layer ACT1 may be exposed.

The extension portion EX of the first active layer ACT1 may extend from the first upper capacitor electrode CCE in a direction opposite to the second direction DR2, hereinafter referred to as a second reverse direction.

The first active layer ACT1 may overlap the capacitor electrode CCE described above in the third direction DR3. The first capacitor C1 may be formed in an overlapping region between the first active layer ACT1 and the capacitor electrode CCE. For example, the first capacitor C1 may be formed between a portion corresponding to the first electrode E11 of the first active layer ACT1 among the first active layer ACT1 and the capacitor electrode CCE overlapping the first electrode E11 in the third direction DR3. The capacitor electrode CCE and the first electrode E11 of the first active layer ACT1 may be the first electrode and the second electrode of the first capacitor C1 described above, respectively.

The first active layer ACT1 may include a material such as polycrystalline silicon, single crystal silicon, low-temperature polycrystalline silicon, amorphous silicon and an oxide semiconductor. When the first active layer ACT1 includes an oxide semiconductor material, the first active layer ACT1 may include indium-gallium-zinc-oxide (IGZO). When the first active layer ACT1 includes polycrystalline silicon or an oxide semiconductor material, the source region and the drain region of the first active layer ACT1 may be doped with ions and thus may be conductive regions.

The third conductive layer 333 may be disposed on the second conductive layer 222 in the third direction DR3. An insulating film may not be disposed between the second conductive layer 222 and the third conductive layer 333. As shown in FIGS. 6, 9, 12 and 13, the third conductive layer 333 may include a second active layer ACT2.

The second active layer ACT2 may include a second-first active layer ACT2-1, a second-second active layer ACT2-2, and a second-third active layer ACT2-3.

A part of the second active layer ACT2 may form the second to fifth transistors T2 to T5 together with second to fifth gate electrodes GE2 to GE5 to be described later. For example, as shown in FIGS. 9 and 12, the second-first active layer ACT2-1 may include a first electrode E21 of the second transistor T2, a second electrode E22 of the second transistor T2, a second channel region CH2 of the second transistor T2, a first electrode E31 of the third transistor T3, a second electrode E32 of the third transistor T3, and a third channel region CH3 of the third transistor T3. In addition, the second-second active layer ACT2-2 may include a first electrode E41 of the fourth transistor T4, a second electrode E42 of the fourth transistor T4, and a fourth channel region CH4 of the fourth transistor T4. Further, the second-third active layer ACT2-3 may include a first electrode E51 of the fifth transistor T5, a second electrode E52 of the fifth transistor T5, and a fifth channel region CH5 of the fifth transistor T5.

Here, the first electrode of each of the second to fifth transistors T2 to T5 may be one of the source electrode and the drain electrode of the respective transistors, and second electrode of each of the second to fifth transistors T2 to T5 may be the other one of the source electrode and the drain electrode of the respective transistors.

The second active layer ACT2 may include a material such as polycrystalline silicon, single crystal silicon, low-temperature polycrystalline silicon, amorphous silicon and an oxide semiconductor. When the second active layer ACT2 includes an oxide semiconductor material, the second active layer ACT2 may include indium-gallium-zinc-tin oxide (IGZTO). When the second active layer ACT2 includes polycrystalline silicon or an oxide semiconductor material, the source region and the drain region of the second active layer ACT2 may be doped with ions and thus may be conductive regions.

The second active layer ACT2 may include a material different from that of the first active layer ACT1. For example, when the first active layer ACT1 described above is an oxide semiconductor including indium-gallium-zinc-oxide (IGZO), the second active layer ACT2 may be an oxide semiconductor including indium-gallium-zinc-tin oxide (IGZTO). As such, the first transistor T1, which is a driving transistor requiring high reliability, may include the first active layer ACT1 of indium-gallium-zinc-oxide (IGZO), while each of the second to fifth transistors T2 to T5, which are switching transistors requiring high switching speed, may include a second active layer ACT2 of indium-gallium-zinc-tin oxide (IGZTO). In other words, the driving transistor, e.g., the first transistor T1, and the switching transistor, e.g., the second to fifth transistors T2 to T5, may include a heterogeneous oxide semiconductor material. Accordingly, both high reliability and high speed of the pixel circuit PC can be satisfied.

Meanwhile, since the first active layer ACT1 and the second active layer ACT2 are semiconductor layers made of different materials, the first active layer ACT1 and the second active layer ACT2 may be formed on the substrate through different processes. The first active layer ACT1 and the second active layer ACT2 may be connected by a connection electrode, hereinafter referred to as an active connection electrode. For example, since the active connection electrode may be included in a fifth conductive layer 555 to be described later, one side of the active connection electrode may be connected to the first active layer ACT1 through a contact hole, e.g., first-type contact hole CTa, penetrating the insulating film, and the other side of the active connection electrode may be connected to the second active layer ACT2 through another contact hole, e.g., first-type contact hole CTa, penetrating the insulating film. However, in this case, since contact holes, for example, at least two first-type contact holes CTa, and active connection electrode for connecting different types of active layers are separately required, the pixel area, aperture ratio and the likes may decrease.

According to the present embodiment, different types of active layers may be directly connected without a contact hole of the insulating film. As an example of this, as shown in portion A of FIG. 13 (or FIG. 12), at least a portion of the second active layer ACT2 may be directly connected to at least a portion of the first active layer ACT1. In other words, at least a portion of the second active layer ACT2 may be in direct contact with at least a portion of the first active layer ACT1. For example, the second-third active layer ACT2-3 may be in direct contact with the extension portion EX of the first active layer ACT1. For example, a portion corresponding to the second electrode E52 of the fifth transistor T5 among the second-third active layer ACT2-3 may be in direct contact with a portion corresponding to the second electrode E12 of the first transistor T1 among the first active layer ACT1. Like described above, since the conductive region of the second-third active layer ACT2-3 and the conductive region of the first active layer ACT1 are in direct contact without a contact hole, the first active layer ACT1 and the second-third active layer ACT2-3 are may be directly electrically connected to each other. In this case, the second-third active layer ACT2-3 and the first active layer ACT1 may overlap in the third direction DR3. For example, in a contact region, e.g., portion A, of the second-third active layer ACT2-3 and the first active layer ACT1, the second-third active layer ACT2-3 and the first active layer ACT1 may overlap in the third direction DR3.

As described above, since the first active layer ACT1 and the second active layer ACT2 are directly connected to each other and separate contact holes and active connection electrodes are not required to connect them, space utilization of pixels can be improved. For example, since the contact holes and the active connection electrode described above may be omitted, the power line, e.g., the upper reference voltage line VRLb, included in the fifth conductive layer 555 or a portion of a first upper driving voltage line VDLb may extend to the area in which the omitted active connection electrode is disposed to increase the area of the power line, and as a result, the capacitance of the first capacitor C1 may be further increased. In addition, generation of parasitic capacitors between heterogeneous active layers and active connection electrodes for connecting the heterogeneous active layers may be suppressed. In addition, since the first active layer ACT1 and the second active layer ACT2 are disposed on substantially the same layer, in contrast to when the first active layer ACT1 and the second active layer ACT2 are disposed on insulating layers having different heights, the problem of a step difference of the active connection electrode can be solved.

Additionally, or alternatively, as in the example shown in portion B of FIG. 13 (or FIG. 12), the second-second active layer ACT2-2 may be in direct contact with the first active layer ACT1. For example, a portion corresponding to the first electrode E41 of the fourth transistor T4 among the second-second active layer ACT2-2 may be in direct contact with a portion corresponding to the first electrode E11 of the first transistor T1 among the first active layer ACT1. As described above, since the first active layer ACT1 and the second-second active layer ACT2-2 are in direct contact with each other without a contact hole, the first active layer ACT1 and the second-second active layer ACT2-2 may be electrically connected to each other. At this time, the second-second active layer ACT2-2 and the first active layer ACT1 may overlap in the third direction DR3. For example, in the contact region between the second-second active layer ACT2-2 and the first active layer ACT1, the second-second active layer ACT2-2 and the first active layer ACT1 may overlap each other in the third direction DR3.

The fourth conductive layer 444 may be disposed on the third conductive layer 333 along the third direction DR3. An insulating film may be disposed between the third conductive layer 333 and the fourth conductive layer 444. As shown in FIGS. 6, 10 and 12, the fourth conductive layer 444 may include a third gate electrode GE3, a second gate electrode GE2, the first gate electrode GE1, a fifth gate electrode GE5, and a fourth gate electrode GE4.

The first gate electrode GE1 may be an upper gate electrode of the first transistor T1. As shown in FIG. 12, the first gate electrode GE1 may overlap a portion of the first active layer ACT1, e.g., the extension portion EX of the first active layer ACT1, in the third direction DR3. As shown in FIGS. 8 and 12, the first channel region CH1 of the first transistor T1 may be formed in an overlapping region between the first gate electrode GE1 and the first active layer ACT1, and each of the first electrode E11 and the second electrode E12 of the first transistor T1 may be formed in the first active layer ACT1 regions on both sides of the first channel region CH1, respectively.

In addition, as shown in FIGS. 6-8, the first gate electrode GE1 may overlap the first counter gate electrode GEb1 in the third direction DR3. The first channel region CH1 of the first active layer ACT1 described above may be disposed between the first gate electrode GE1 and the first counter gate electrode GEb1.

The second gate electrode GE2 may be an upper gate electrode of the second transistor T2. As shown in FIG. 12, the second gate electrode GE2 may overlap a portion of the second-first active layer ACT2-1 in the third direction DR3. As shown in FIGS. 9 and 12, the second channel region CH2 of the second transistor T2 may be formed in the overlapping region of the second gate electrode GE2 and the second-first active layer ACT2-1, and each of the first electrode E21 and the second electrode E22 of the second transistor T2 may be formed in the first active layer ACT1 regions on both sides of the second channel region CH2, respectively.

In addition, as shown in FIGS. 6, 7, and 9, the second gate electrode GE2 may overlap the second counter gate electrode GEb2 in the third direction DR3. The second channel region CH2 of the second-first active layer ACT2-1 described above may be disposed between the second gate electrode GE2 and the second counter gate electrode GEb2.

The third gate electrode GE3 may be an upper gate electrode of the third transistor T3. As shown in FIG. 12, the third gate electrode GE3 may overlap a portion of the second-first active layer ACT2-1 in the third direction DR3. As shown in FIGS. 9 and 12, the third channel region CH3 of the third transistor T3 may be formed in the overlapping region of the third gate electrode GE3 and the second-first active layer ACT2-1, and each of the first electrode E31 and the second electrode E32 of the third transistor T3 may be formed in the second-first active layer ACT2-1 regions on both sides of the third channel region CH3, respectively.

In addition, as shown in FIGS. 6, 7 and 9, the third gate electrode GE3 may overlap the third counter gate electrode GEb3 in the third direction DR3. The third channel region CH3 of the second-first active layer ACT2-1 described above may be disposed between the third gate electrode GE3 and the third counter gate electrode GEb3.

The fourth gate electrode GE4 may be an upper gate electrode of the fourth transistor T4. As shown in FIG. 12, the fourth gate electrode GE4 may overlap a portion of the second-second active layer ACT2-2 in the third direction DR3. As shown in FIGS. 9 and 12, the fourth channel region CH4 of the fourth transistor T4 may be formed in the overlapping region of the fourth gate electrode GE4 and the second-second active layer ACT2-2, and each of the first electrode E41 and the second electrode E42 of the fourth transistor T4 may be formed in the second-second active layer ACT2-2 regions on both sides of the fourth channel region CH4, respectively.

In addition, as shown in FIGS. 6, 7, and 9, the fourth gate electrode GE4 may overlap the fourth counter gate electrode GEb4 in the third direction DR3. The fourth channel region CH4 of the second-second active layer ACT2-2 described above may be disposed between the fourth gate electrode GE4 and the fourth counter gate electrode GEb4.

The fifth gate electrode GE5 may be an upper gate electrode of the transistor T5. As shown in FIG. 12, the fifth gate electrode GE5 may overlap a portion of the second-third active layer ACT2-3 in the third direction DR3. As shown in FIGS. 9 and 12, the fifth channel region CH5 of the fifth transistor T5 may be formed in the overlapping region of the fifth gate electrode GE5 and the second-third active layer ACT2-3, and each of the first electrode E51 and the second electrode E52 of the fifth transistor T5 may be formed in the second-third active layer ACT2-3 regions on both sides of the fifth channel region CH5, respectively.

In addition, as shown in FIGS. 6, 7, and 9, the fifth gate electrode GE5 may overlap the fifth counter gate electrode GEb5 in the third direction DR3. The fifth channel region CH5 of the second-third active layer ACT2-3 described above may be disposed between the fifth gate electrode GE5 and the fifth counter gate electrode GEb5.

The fifth conductive layer 555 may be disposed on the fourth conductive layer 444 along the third direction DR3. An insulating film may be disposed between the fourth conductive layer 444 and the fifth conductive layer 555. As shown in FIGS. 6 and 11, the fifth conductive layer 555 may include the data line DL, the first upper driving voltage line VDLb, the upper reference voltage line VRLb, a third gate connection electrode GCE3, a second gate connection electrode GCE2, a first gate connection electrode GCE1, a pixel connection electrode PCE, a counter gate connection electrode GCEb, a fifth gate connection electrode GCE5, a source connection electrode SCE, and a fourth gate connection electrode GCE4.

The data line DL may extend along the second direction DR2. As shown in FIGS. 6 and 9, the data line DL may be connected to the first electrode E21 of the second transistor T2 through a contact hole, e.g., the first-type contact hole CTa, of the insulating film. For example, the data line DL may be connected to a portion corresponding to the first electrode E21 of the second transistor T2 among the second-first active layer ACT2-1 through the contact hole of the insulating film described above.

In addition, as shown in FIG. 6, the data line DL may overlap the shielding electrode SHE in the third direction DR3.

The first upper driving voltage line VDLb may extend in the second direction DR2. As shown in FIG. 6, the first upper driving voltage line VDLb may be connected to a first lower driving voltage line VDLa through a contact hole, e.g., the first-type contact hole CTa, of the insulating film. A plurality of first upper driving voltage lines VDLb and a plurality of first lower driving voltage lines VDLa connected thereto may form the first driving voltage line VDL. The first driving voltage line VDL including the plurality of first upper driving voltage lines VDLb and the plurality of first lower driving voltage lines VDLa crossing them may have a mesh shape.

In addition, as shown in FIG. 6, the first upper driving voltage line VDLb may be connected to the shielding electrode SHE through a contact hole, e.g., a type 1 contact hole CTa, of the insulating film.

In addition, as shown in FIGS. 6 and 9, the first upper driving voltage line VDLb may be connected to the first electrode E51 of the fifth transistor T5 through a contact hole, e.g., the first-type contact hole CTa, of the insulating film. For example, the data first upper driving voltage line VDLb may be connected to a portion corresponding to the first electrode E51 of the fifth transistor T5 among the second-third active layer ACT2-3 through the first-type contact hole CTa, e.g., a first contact hole CT1, described above.

As shown in FIGS. 6 and 8, the first upper driving voltage line VDLb may overlap the first active layer ACT1 in the third direction DR3. The second capacitor C2 may be formed in an overlapping region between the first upper driving voltage line VDLb and the first active layer ACT1. For example, the second capacitor C2 may be formed between a portion corresponding to the first electrode E11 of the first transistor T1 among the first active layer ACT1 and the first upper driving voltage line VDLb overlapping the first electrode E11 in the third direction DR3. The first upper driving voltage line VDLb and the first active layer ACT1 may be the first electrode and the second electrode of the second capacitor C2, respectively.

The upper reference voltage line VRLb may extend along the second direction DR2. As shown in FIG. 6, the upper reference voltage line VRLb may be connected to the lower reference voltage line VRLa through a contact hole, e.g., a first-type contact hole CTa, of the insulating film. The plurality of upper reference voltage lines VRLb and the plurality of lower reference voltage lines VRLa connected thereto may form a reference voltage line VRL. The reference voltage line VRL including the plurality of upper reference voltage lines VRLb and the plurality of lower reference voltage lines VRLa crossing the plurality of upper reference voltage lines VRLb may have a mesh shape.

In addition, as shown in FIGS. 6 and 9, the upper reference voltage line VRLb may be connected to the second-first active layer ACT2-1 through a contact hole, e.g., the first-type contact hole CTa, of the insulating film. For example, the upper reference voltage line VRLb may be connected to a portion corresponding to the first electrode E31 of the third transistor T3 among the second-first active layer ACT2-1 through the first-type contact hole CTa described above.

The first gate connection electrode GCE1 may extend along the second direction DR2. At this time, the first gate connection electrode GCE1 may have a curved shape to bypass the pixel connection electrode PCE and may extend along the second direction DR2. As shown in FIGS. 6 and 9, the first gate connection electrode GCE1 may be connected to the second electrode E22 of the second transistor T2 through a contact hole, e.g., the first-type contact hole CTa, of the insulating film. For example, the first gate connection electrode GCE1 may be connected to a portion corresponding to the second electrode E22 of the second transistor T2 among the second-first active layer ACT2-1 through the first-type contact hole CTa described above.

In addition, the first gate connection electrode GCE1 may be connected to the capacitor electrode CCE through a contact hole, e.g., the first-type contact hole CTa or fifth contact hole CT5, of the insulating film and the hole 40 of the first active layer ACT1.

Also, the first gate connection electrode GCE1 may be connected to the first gate electrode GE1 through a contact hole, e.g., the first-type contact hole CTa or second contact hole CT2, of the insulating film.

As shown in FIG. 6, the second gate connection electrode GCE2 may be connected to the second gate electrode GE2 through a contact hole, e.g., the first-type contact hole CTa, of the insulating film.

In addition, the second gate connection electrode GCE2 may be connected to the first gate line GWL through a contact hole, e.g., the first-type contact hole CTa, of the insulating film.

As shown in FIG. 6, the fourth gate connection electrode GCE4 may be connected to the fourth gate electrode GE4 through a contact hole, e.g., the first-type contact hole CTa, of the insulating film.

In addition, the fourth gate connection electrode GCE4 may be connected to the second gate line GIL through a contact hole, e.g., the first-type contact hole CTa, of the insulating film.

As shown in FIG. 6, the fifth gate connection electrode GCE5 may be connected to the fifth gate electrode GE5 through a contact hole, e.g., the first-type contact hole CTa, of the insulating film.

In addition, the fifth gate connection electrode GCE5 may be connected to the emission control line EML through a contact hole e.g., the first-type contact hole CTa, of the insulating film.

As shown in FIG. 6, the counter gate connection electrode GCEb may be connected to the first counter gate electrode GEb1 through a contact hole, e.g., the first-type contact hole CTa, of the insulating film.

In addition, the counter gate connection electrode GCEb may be connected to the first active layer ACT1 through a contact hole, e.g., the first-type contact hole CTa, of the insulating film. For example, the counter gate connection electrode GCEb may be connected to a portion corresponding to the first electrode E11 of the first transistor T1 among the first active layer ACT1 through the first-type contact hole CTa described above.

As shown in FIGS. 6 and 9, the source connection electrode SCE may be connected to the second-second active layer ACT2-2 through a contact hole, e.g., the first-type contact hole CTa,) of the insulating film. For example, the source connection electrode SCE may be connected to the second electrode E42 of the fourth transistor T4 in the second-second active layer ACT2-2 through the first-type contact hole CTa described above.

In addition, the source connection electrode SCE may be connected to the initialization voltage line VIL through a contact hole e.g., the first-type contact hole CTa, of the insulating film.

The pixel connection electrode PCE may be positioned in a groove defined by a curved portion of the first gate connection electrode GCE1. At least a portion of the pixel connection electrode PCE may be surrounded by the curved portion of the first gate connection electrode GCE1.

In addition, as shown in FIGS. 6 and 9, the pixel connection electrode PCE may be connected to the second-second active layer ACT2-2 through a contact hole, e.g., the first-type contact hole CTa or third contact hole CT3, of the insulating film. For example, the pixel connection electrode PCE may be connected to a portion corresponding to the first electrode E41 of the fourth transistor T4 among the second-second active layer ACT2-2 through the first-type contact hole CTa or the third contact hole CT3 described above.

FIG. 14 is a cross-sectional view taken along line I-I′ of FIG. 6, and FIG. 15 is a cross-sectional view taken along line II-II′ of FIG. 6.

As shown in FIG. 14, the display device 10 may include the substrate SUB, a barrier film BR, the thin-film transistor layer TFTL, the light-emitting element layer EMTL, and an encapsulation layer ENC. The barrier film BR, the thin-film transistor layer TFTL, the light-emitting element layer EMTL and the encapsulation layer ENC may be sequentially disposed on the substrate SUB in the third direction DR3. The thin-film transistor layer TFTL may include the above-described pixel circuit PC.

The substrate SUB may be a rigid substrate or a flexible substrate that can be bent, folded, rolled, and so on. The substrate SUB may be made of an insulating material such as glass, quartz and a polymer resin. Examples of the polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (CAT), cellulose acetate propionate (CAP) or a combination thereof. Alternatively, the substrate SUB may include a metal material.

The barrier film BR may be disposed on the substrate SUB. The barrier film BR may be a film for protecting the transistors T1 to T5 of the thin-film transistor layer TFTL and an emissive layer EL of the light-emitting element layer EMTL from the moisture permeating through the substrate SUB that is vulnerable to moisture. The barrier film BR may be made up of multiple inorganic layers stacked on one another alternately. For example, the buffer layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

The first conductive layer 111, e.g., see FIG. 7, may be disposed on the barrier film BR. For example, as shown in FIGS. 6, 14 and 15, the second driving voltage line VSL, the lower reference voltage line VRLa, the third gate line GRL, the first gate line GWL, the shielding electrode SHE, the emission control line EML, the initialization voltage line VIL, the second gate line GIL, the capacitor electrode CCE, and the first counter gate electrode GEb1 may be disposed on the barrier film BR. In the view shown in FIG. 14, the emission control line EML, the fifth counter gate electrode Geb5, the first counter gate electrode GEb1, and the capacitor electrode CCE are disposed on the barrier film BR. In addition, in the view shown in FIG. 15, the shielding electrode SHE and the capacitor electrode CCE are disposed on the barrier film BR.

A buffer layer BF may be disposed on the first conductive layer 111. The buffer layer BF may be disposed on the entire surface of the substrate SUB including the first conductive layer 111. The buffer layer BF may be a layer for protecting the transistors of the thin-film transistor layer TFTL and the emissive layer EL of the light-emitting element layer EMTL from the moisture permeating through the substrate SUB that is vulnerable to moisture. The buffer layer BF may be made up of multiple inorganic layers stacked on one another alternately. For example, the buffer layer BF may be made up of multiple layers in which one or more inorganic layers of a silicon nitride layer, a silicon oxynitride layer, a silicon oxide layer, a titanium oxide layer and an aluminum oxide layer are alternately stacked on one another.

The second conductive layer 222, e.g., see FIG. 8, and an interlayer insulating layer ITL may be disposed on the buffer layer BF. For example, as shown in FIGS. 6, 14 and 15, the first active layer ACT1 may be disposed on the buffer layer BF. In the example shown in FIG. 14, the first active layer ACT1 including the first electrode E11 of the first transistor T1, the first channel region CH1 of the first transistor T1, and the second electrode E12 of the first transistor T1 may be disposed on the buffer layer BF. As shown in FIG. 14, the first active layer ACT1 may be disposed on the buffer layer BF such that the first channel region CH1 of the first active layer ACT1 overlaps with the first counter gate electrode GEb1 in the third direction DR3 and the first electrode E11 of the first active layer ACT1 overlaps with the capacitor electrode CCE. In addition, in the view shown in FIG. 15, the first active layer ACT1 including the first electrode E11 of the first transistor T1 and the interlayer insulating layer ITL may be disposed on the buffer layer BF. Further, in the example shown in FIG. 15, the first capacitor C1 is formed between the first active layer ACT1 and the capacitor electrode CCE.

The first active layer ACT1 may be, for example, oxide semiconductor. For example, the first active layer ACT1 may be an oxide semiconductor that includes indium-gallium-zinc-oxide (IGZO).

The third conductive layer 333, e.g., see FIG. 9, may be disposed on the buffer layer BF and the second conductive layer 222. For example, as shown in FIGS. 14 and 15, the second active layer ACT2 may be disposed on the buffer layer BF and the first active layer ACT1. In the view shown in FIG. 14, the second-third active layer ACT2-3 including the first electrode E51 of the fifth transistor T5, the fifth channel region CH5 of the fifth transistor T5, and the second electrode E52 of the fifth transistor T5 is disposed on the buffer layer BF and the second conductive layer 222, e.g., the first active layer ACT1. The second-third active layer ACT2-3 may be disposed on the buffer layer BF and the first active layer ACT1 such that the fifth channel region CH5 of the second-third active layer ACT2-3 overlaps with the fifth counter gate electrode GEb5 and the second electrode E52 of the second-third active layer ACT2-3 overlaps with the second electrode E12 of the first active layer ACT1. In addition, as shown in portion A of FIG. 14, the second electrode E52 of the second-third active layer ACT2-3 may be in direct contact with the second electrode E12 of the first active layer ACT1. In addition, as shown in portion A of FIG. 14, the second electrode E52 of the second-third active layer ACT2-3 may be in direct contact with the second electrode E12 of the first active layer ACT1 at the side surface of the first active layer ACT1. In other words, the second electrode E52 of the second-third active layer ACT2-3 may be in direct contact with the upper and side surfaces of the second electrode E12 of the first active layer ACT1. Further, as shown in portion B of FIG. 14, the first electrode E41 of the second-second active layer ACT2-2 may be in direct contact with the first electrode E11 of the first active layer ACT1. In addition, as shown in portion B of FIG. 14, the first electrode E41 of the second-second active layer ACT2-2 may be in direct contact with the second electrode E12 of the first active layer ACT1 at the side surface of the first active layer ACT1. In other words, the first electrode E41 of the second-second active layer ACT2-2 may be in direct contact with the upper and side surfaces of the first electrode E11 of the first active layer ACT1.

The second active layer ACT2 may include a material different from that of the first active layer ACT1. For example, the second active layer ACT2 may be an oxide semiconductor including indium-gallium-zinc-tin oxide (IGZTO).

In addition, a first gate insulating layer GTI1 may be further disposed on the second conductive layer 222 described above. For example, as shown in FIG. 14, the first gate insulating layer GTI1 may be disposed to overlap a channel region, e.g., the first channel region CH1, of the first active layer ACT1. For example, since the first active layer ACT1 includes the first channel region CH1 of the first transistor T1, the first gate insulating layer GTI1 may be disposed on the first active layer ACT1 so that first channel region CH1 overlaps in the third direction DR3. Meanwhile, when the first active layer ACT1 includes a plurality of channel regions for each of the plurality of transistors, the first gate insulating layer GTI1 described above may be disposed on the first active layer ACT1 to overlap each of the plurality of channel regions.

The first gate insulating layer GTI1 may include at least one of tetraethoxysilane (TetaraEthylOrthoSilicate, TEOS), silicon nitride (SiNx), and silicon oxide (SiO₂). For example, the first gate insulating layer GTI1 may have a double layer structure in which a silicon nitride layer having the thickness of 40 nm and a tetraethoxysilane layer having the thickness of 80 nm are stacked on one another.

A second gate insulating layer GTI2 may be disposed on the first gate insulating layer GTI1. For example, as shown in FIG. 14, the second gate insulating layer GTI2 may be disposed on the first gate insulating layer GTI1.

The second gate insulating layer GTI2 may have the same material or structure as the first gate insulating layer GTI1 described above.

In addition, the second gate insulating layer GTI2 described above may be further disposed on the third conductive layer 333. For example, the second gate insulating layer GTI2 may be disposed on each channel region of the second active layer ACT2. In the example shown in FIG. 14, the second gate insulating layer GTI2 is disposed such that the second gate insulating layer GTI2 overlaps the fifth channel region CH5 of the second-third active layer ACT2-3. Meanwhile, the second gate insulating layer GTI2 may be disposed on the second active layer ACT2 such that the second gate insulating layer GTI2 corresponds to the entire channel regions of the second active layer ACT2, for example, the second to fifth channel regions CH2 to CH5.

The fourth conductive layer 444, e.g., see FIG. 10, may be disposed on the second gate insulating layer GTI2. For example, as shown in FIGS. 6, 14 and 15, the first gate electrode GE1, the second gate electrode GE2, the third gate electrode GE3, the fourth gate electrode GE4 and the fifth gate electrode GE5 may be disposed on the second gate insulating layer GTI2. In the view shown in FIG. 14, the first gate electrode GE1 and the fifth gate electrode GE5 are disposed on the second gate insulating layer GTI2. The first gate electrode GE1 may be disposed on the second gate insulating layer GTI2 to correspond to the first channel region CH1 of the first active layer ACT1, and the fifth gate electrode GE5 may be disposed on the second gate insulating layer GTI2 to correspond to the fifth channel region CH5 of the second-third active layer ACT2-3. Meanwhile, the second gate electrode GE2, the third gate electrode GE3, and the fourth gate electrode GE4 may be disposed on the second active layer ACT2 to overlap the second channel region CH2, the third channel region CH3, and the fourth channel region CH4, respectively.

The interlayer insulating layer ITL may be disposed on the fourth conductive layer 444, the third conductive layer 333, the second conductive layer 222 and the buffer layer BF. The interlayer insulating layer ITL may be disposed on the entire surface of the substrate including the third to fourth conductive layers 333 to 444. In the views shown in FIGS. 14 and 15, the interlayer insulating layer ITL is disposed on the first active layer ACT1, the second active layer ACT2, the first gate electrode GE1, the fifth gate electrode GE5, and the buffer layer BF. The interlayer insulating layer ITL may have a thickness greater than the thickness of the first gate insulating layer GTI1. Here, the thickness may refer to the size in the third direction DR3.

The interlayer insulating layer ITL may include an inorganic layer, for example, a silicon nitride layer, a silicon oxynitride layer, a silicon oxide layer, a titanium oxide layer, or an aluminum oxide layer. The interlayer insulating layer ITL may include a number of inorganic layers.

The fifth conductive layer 555, e.g., see FIG. 11, may be disposed on the interlayer insulating layer ITL. For example, as shown in FIGS. 6, 14 and 15, the data line DL, the first upper driving voltage line VDLb, the upper reference voltage line VRLb, the third gate connection electrode GCE3, the second gate connection electrode GCE2, the first gate connection electrode GCE1, the pixel connection electrode PCE, the counter gate connection electrode GECb, the fifth gate connection electrode GCE5, the source connection electrode SCE, and the fourth gate connection electrode GCE4 may be disposed on the interlayer insulating layer ITL. In the view shown in FIG. 14, the first upper driving voltage line VDLb, the fifth gate connection electrode GCE5, the first gate connection electrode GCE1 and the pixel connection electrode PCE are disposed on the interlayer insulating layer ITL. The first upper driving voltage line VDLb may be connected to the first electrode E51 of the fifth transistor T5 through the first contact hole CT1 penetrating the interlayer insulating layer ITL. The fifth gate connection electrode GCE5 may be disposed on the interlayer insulating layer ITL to overlap the fifth gate electrode GE5. The first gate connection electrode GCE1 may be connected to the first gate electrode GE1 through the second contact hole CT2 penetrating the interlayer insulating layer ITL. The pixel connection electrode PCE may be connected to the first electrode E11 of the first transistor T1 through the third contact hole CT3 penetrating through the interlayer insulating layer ITL. In addition, in the view shown in FIG. 15, the data line DL, the first upper driving voltage line VDLb and the first gate connection electrode GCE1 are disposed on the interlayer insulating layer ITL. The data line DL may be disposed on the interlayer insulating layer ITL to overlap the shielding electrode SHE. Since the first upper driving voltage line VDLb may be disposed on the interlayer insulating layer ITL to overlap the first electrode E11 of the first active layer ACT1, the second capacitor C2 may be formed on an overlapping region between the first upper driving voltage line VDLb and the first electrode E11 of the first active layer ACT1. The first gate connection electrode GCE1 may be connected to the capacitor electrode CCE through the fifth contact hole CT5 penetrating the interlayer insulating layer ITL, the hole 40 of the first active layer ACT1, and the buffer layer BF. Meanwhile, the first contact hole CT1, the second contact hole CT2, the third contact hole CT3, a fourth contact hole CT4, and the fifth contact hole CT5 may correspond to and be the first-type contact hole CTa described above.

A planarization layer VIA may be disposed on the fifth conductive layer 555 and the interlayer insulating layer ITL. The planarization layer VIA may be disposed on the entire surface of the substrate SUB including the fifth conductive layer 555 and the interlayer insulating layer ITL. For example, as shown in FIGS. 14 and 15, the planarization layer VIA may be disposed on the entire surface of the substrate SUB that includes the first upper driving voltage line VDLb, the fifth gate connection electrode GCE5, the first gate connection electrode GCE1, the pixel connection electrode PCE, the data line DL and the interlayer insulating layer ITL.

The planarization layer VIA may include an organic layer such as an acryl resin, an epoxy resin, a phenolic resin, a polyamide resin and a polyimide resin.

The light-emitting element layer EMTL including the sixth conductive layer may be disposed on the planarization layer VIA. For example, as shown in FIGS. 14 and 15, the pixel electrode PE may be disposed as the sixth conductive layer on the planarization layer VIA. In the examples shown in FIGS. 14 and 15, the pixel electrode PE is disposed on the planarization layer VIA. As shown in FIG. 14, the pixel electrode PE may be connected to the pixel connection electrode PCE through the fourth contact hole CT4 penetrating the planarization layer VIA. It should be noted that the fourth contact hole CT4 may correspond to and be the second-type contact hole CTb described above.

The light-emitting element layer EMTL described above may further include a plurality of light-emitting elements LEL and a bank PDL (or pixel-defining layer) in addition to the sixth conductive layer.

The light-emitting elements LEL may include, for example, a first light-emitting element, a second light-emitting element, and a third light-emitting element. The first light-emitting element may include a first pixel electrode, a first emissive layer, and a common electrode CM. The second light-emitting element may include a second pixel electrode, a second emissive layer, and a common electrode CM. The third light-emitting element may include a third pixel electrode, a third emissive layer, and a common electrode CM. Hereinafter, the first light-emitting element LEL will be described as a representative of the light-emitting elements.

The first light-emitting element LEL may include the first pixel electrode PE, the emissive layer EL, and the common electrode CM. In an emission area EA, the first pixel electrode PE, the emissive layer EL and the common electrode CM are stacked on one another sequentially, so that holes from the first pixel electrode PE and electrons from the common electrode CM are combined with each other in the emissive layer to emit light. In this instance, the first pixel electrode PE may be an anode electrode of the light-emitting element LEL, and the common electrode CM may be a cathode electrode of the light-emitting element LEL.

In the top-emission structure where light exits from the emissive layer EL toward the common electrode CM, the first pixel electrode PE may be made up of a single layer of molybdenum (Mo), titanium (Ti), copper (Cu) or aluminum (Al), or may be made up of a stack structure of aluminum and titanium (Ti/Al/Ti), a stack structure of aluminum and ITO (ITO/AI/ITO), an APC alloy and a stack structure of APC alloy and ITO (ITO/APC/ITO) in order to increase the reflectivity. The APC alloy is an alloy of silver (Ag), palladium (Pd) and copper (Cu).

The bank PDL (or pixel-defining film) may define the emission areas EA of the pixels. To this end, the bank PDL may be disposed to expose a part of the first pixel electrode PE on the planarization layer. The bank PDL may cover an edge of the first pixel electrode PE. Although not shown in the drawings, the bank PDL may be disposed in the fourth contact hole CT4 penetrating the planarization layer. Accordingly, the fourth contact hole CT4 penetrating the planarization layer may be filled with the bank PDL. The bank PDL may be formed of an organic layer such as an acryl resin, an epoxy resin, a phenolic resin, a polyamide resin and a polyimide resin.

As shown in FIG. 14, a spacer SPC may be disposed on the bank PDL. The spacer SPC may support a mask during a process of fabricating the emissive layer EL. The spacer SPC may be formed of an organic layer such as an acryl resin, an epoxy resin, a phenolic resin, a polyamide resin and a polyimide resin.

The emissive layer EL may be formed on the first pixel electrode PE. The emissive layer EL may include an organic material to emit light of a certain color. For example, the emissive layer EL may include a hole transporting layer, an organic material layer, and an electron transporting layer. The organic material layer may include a host and a dopant. The organic material layer may include a material that emits a predetermined light, and may be formed using a phosphor or a fluorescent material.

For example, the organic material layer of the first emissive layer in the first emission area that emits light of the first color may be a phosphor that includes a host material including carbazole biphenyl (CBP) or mCP(1,3-bis (carbazol-9-yl), and a dopant including at least one selected from the group consisting of: PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium) and PtOEP(octaethylporphyrin platinum). Alternatively, the organic material layer of the first emissive layer of the first emission area may be, but is not limited to, a fluorescent material including PBD: Eu(DBM)3(Phen) or perylene.

The organic material layer of the second emissive layer of the second emission area, which emits light of the second color, may be a phosphor that includes a host material including CBP or mCP, and a dopant material including ir(ppy)3(fac tris(2-phenylpyridine)iridium). Alternatively, the organic material layer of the second emissive layer of the second emission area emitting light of the second color may be, but is not limited to, a fluorescent material including Alq3(tris (8-hydroxyquinolino)aluminum).

The organic material layer of the emissive layer of the third emission area, which emits light of the third color, may be, but is not limited to, a phosphor that includes a host material including CBP or mCP, and a dopant material including (4,6-F2ppy)2Irpic or L2BD111.

The common electrode CM may be disposed on the first, second and third emissive layers, e.g., emissive layers EL. The common electrode CM may be disposed to cover the first, second and third emissive layers. The common electrode CM may be a common layer disposed across the first to third emissive layers. A capping layer may be formed on the common electrode CM.

In the top-emission structure, the common electrode CM may be formed of a transparent conductive material (TCP) such as ITO and IZO that can transmit light, or a semi-transmissive metal material such as magnesium (Mg), silver (Ag) and an alloy of magnesium (Mg) and silver (Ag). When the common electrode CM is formed of a semi-transmissive metal material, the light extraction efficiency can be increased by using microcavities.

The encapsulation layer ENC may be formed on the light-emitting element layer EMTL. The encapsulation layer ENC may include one or more inorganic layers TFE1 and TFE3 to prevent permeation of oxygen or moisture into the light-emitting element layer EMTL. In addition, the encapsulation layer ENC may include at least one organic layer to protect the light-emitting element layer EMTL from particles such as dust. For example, the encapsulation layer ENC may include a first inorganic encapsulation layer TFE1, an organic encapsulation layer TFE2 and a second inorganic encapsulation layer TFE3.

The first inorganic encapsulation layer TFE1 may be disposed on the common electrode CM, the organic encapsulation layer TFE2 may be disposed on the first inorganic encapsulation layer TFE1, and the second inorganic encapsulation layer TFE3 may be disposed on the organic encapsulation layer TFE2. The first inorganic encapsulation layer TFE1 and the second inorganic encapsulation layer TFE3 may be made up of multiple layers in which one or more inorganic layers of a silicon nitride layer, a silicon oxynitride layer, a silicon oxide layer, a titanium oxide layer and an aluminum oxide layer are alternately stacked on one another. The organic encapsulation layer TFE2 may be an organic layer such as an acryl resin, an epoxy resin, a phenolic resin, a polyamide resin, a polyimide resin, etc.

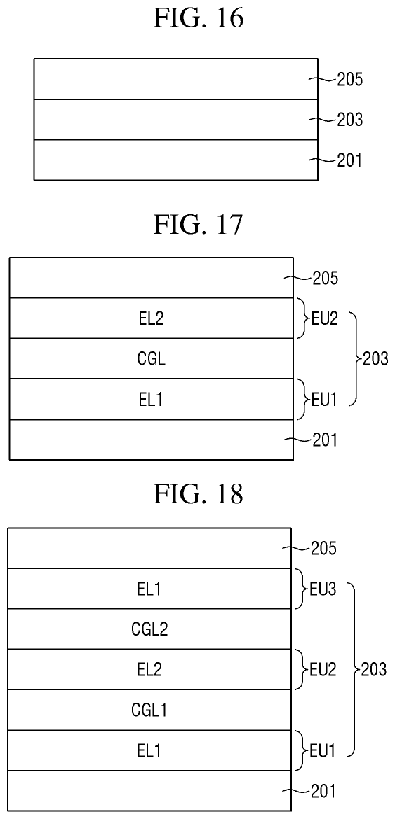

Other structures of a light-emitting element LEL, e.g., see FIG. 14, will be described with reference to FIGS. 16 to 23.

FIG. 16 is a cross-sectional view showing a structure of a display device according to an embodiment of the present disclosure. FIGS. 17 to 20 are cross-sectional views showing structures of a pixel of a display device according to an embodiment of the present disclosure.

Referring to FIG. 16, a light-emitting element, e.g., an organic light-emitting diode, according to an embodiment may include a pixel electrode 201, a common electrode 205, and an intermediate layer 203 between the pixel electrode 201 and the common electrode 205.

The pixel electrode 201 may include a transparent conductive oxide such as indium tin oxide (ITO), indium zinc oxide (IZO), zinc oxide (ZnO), indium oxide (In2O3), indium gallium oxide (IGO) and aluminum zinc oxide (AZO). The pixel electrode 201 may include a reflective layer containing silver (Ag), magnesium (Mg), aluminum (Al), platinum (Pt), palladium (Pd), gold (Au), nickel (Ni), neodymium (Nd), iridium (Ir), chrome (Cr) or a compound thereof. For example, the pixel electrode 201 may have a three-layer structure of ITO/Ag/ITO.

The common electrode 205 may be disposed on the intermediate layer 203. The common electrode 205 may include a method having a low work function, an alloy, an electrically conductive compound, or any combination thereof. For example, the common electrode 205 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The common electrode 205 may be a transmissive electrode, a transflective electrode, or a reflective electrode.

The intermediate layer 203 may include a polymer or a low molecular weight organic material that emits light of a predetermined color. In addition to a variety of organic materials, the intermediate layer 203 may further include metal-containing compounds such as organometallic compounds, inorganic materials such as quantum dots, etc.

According to an embodiment, the intermediate layer 203 may include an emissive layer and a first functional layer and a second functional layer respectively disposed under and on the emissive layer. The first functional layer may include, for example, a hole transport layer HTL or may include a hole transport layer and a hole injection layer HIL. The second functional layer is an optional element disposed on the emissive layer. For example, the intermediate layer 203 may or may not include the second functional layer. The second functional layer may include an electron transport layer ETL and/or an electron injection layer EIL.

According to an embodiment, the intermediate layer 203 may include two or more emitting units sequentially stacked between the pixel electrode 201 and the common electrode 205, and a charge generation layer disposed between the two emitting units. When the intermediate layer 203 includes the emitting units and the charge generation layer, the light-emitting element, e.g., organic light-emitting diode, may have a tandem structure. The light-emitting element, e.g., an organic light-emitting diode, can improve the color purity and the emission efficiency by employing a stack structure of a plurality of emitting units.

One emitting unit may include an emissive layer, and a first functional layer and a second functional layer respectively disposed under and on the emissive layer. The charge generation layer may include a negative charge generation layer and a positive charge generation layer. The emission efficiency of an organic light-emitting diode, which is a tandem light-emitting element having a plurality of emissive layers, can be further increased by the negative charge generating layer and the positive charge generating layer.

The negative charge generation layer may be an n-type charge generation layer. The negative charge generation layer may supply electrons. The negative charge generation layer may include a host and a dopant. The host may include an organic material. The dopant may include a metal material. The positive charge generation layer may be a p-type charge generation layer. The positive charge generation layer may supply holes. The positive charge generation layer may include a host and a dopant. The host may include an organic material. The dopant may include a metal material.

According to an embodiment, as shown in FIG. 17, the light-emitting element, e.g., an organic light-emitting diode, may include a first emitting unit EU1 including a first emissive layer EL1 and a second emitting unit EU2 including a second emissive layer EL2 stacked on each other. A charge generation layer CGL may be disposed between the first emitting unit EU1 and the second emitting unit EU2. For example, the light-emitting element, e.g., an organic light-emitting diode, may include a pixel electrode 201, the first emissive layer EL1, the charge generation layer CGL, the second emissive layer EL2, and a common electrode 205 sequentially stacked on one another. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment, as shown in FIG. 18, the light-emitting element, e.g., an organic light-emitting diode, may include a first light-emitting unit EU1 including a first emissive layer EL1, a third light-emitting unit EU3 including a first emissive layer EL1, and a second light-emitting unit EU2 including a second emissive layer EL2. A first charge generation layer CGL1 may be disposed between the first light-emitting unit EU1 and the second light-emitting unit EU2, and a second charge generation layer CGL2 may be disposed between the second light-emitting unit EU2 and the third light-emitting unit EU3. For example, the light-emitting element, e.g., organic light-emitting diode, may include a pixel electrode 201, the first emissive layer EL1, the first charge generation layer CGL1, the second emissive layer EL2, the second charge generation layer CGL2, the first emissive layer EL1, and a common electrode 205, which are stacked on one another in this order. A first functional layer and a second functional layer may be disposed under and on the first emissive layer EL1, respectively. A first functional layer and a second functional layer may be disposed under and on the second emissive layer EL2, respectively. The first emissive layer EL1 may be a blue emissive layer, and the second emissive layer EL2 may be a yellow emissive layer.

According to an embodiment of the present disclosure, the second light-emitting unit EU2 of the light-emitting element, e.g., organic light-emitting diode, may further include a third light-emitting layer EL3 and/or a fourth light-emitting layer EL4 in direct contact with the second light-emitting unit EU2 under and/or on the second emissive layer EL2 in addition to the second emissive layer EL2. As used herein, the phrase that the third emissive layer EL3 and/or the fourth emissive layer EL4 are in direct contact with the second emissive layer EL2 means that no other layer is disposed between the second emissive layer EL2 and the third emissive layer EL3 and/or between the second emissive layer EL2 and the fourth emissive layer EL4. The third emissive layer EL3 may be a red emissive layer, and the fourth emissive layer EL4 may be a green emissive layer.

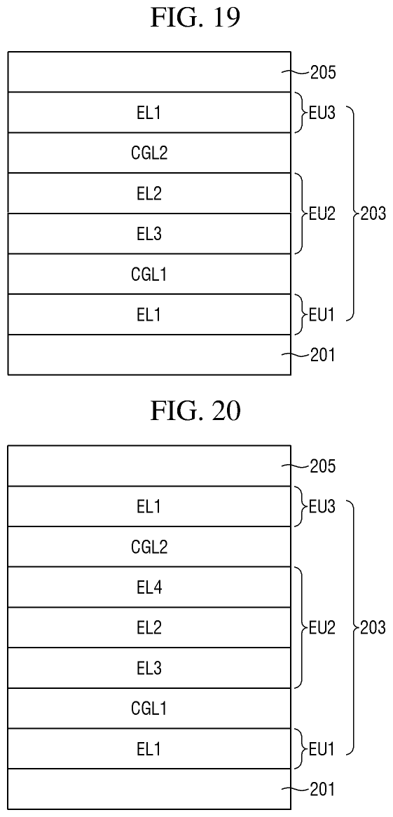

For example, as shown in FIG. 19, the light-emitting element, e.g., organic light-emitting diode, may include a pixel electrode 201, a first emissive layer EL1, a first charge generation layer CGL1, a third emissive layer EL3, a second emissive layer EL2, a second charge generation layer CGL2, a first emissive layer EL1, and a common electrode 205, which are stacked on one another in this order. Alternatively, as shown in FIG. 20, the light-emitting element, e.g., organic light-emitting diode, may include a pixel electrode 201, a first emissive layer EL1, a first charge generation layer CGL1, a third emissive layer EL3, a second emissive layer EL2, a fourth emissive layer EL4, a second charge generation layer CGL2, a first emissive layer EL1, and a common electrode 205, which are stacked on one another in this order.

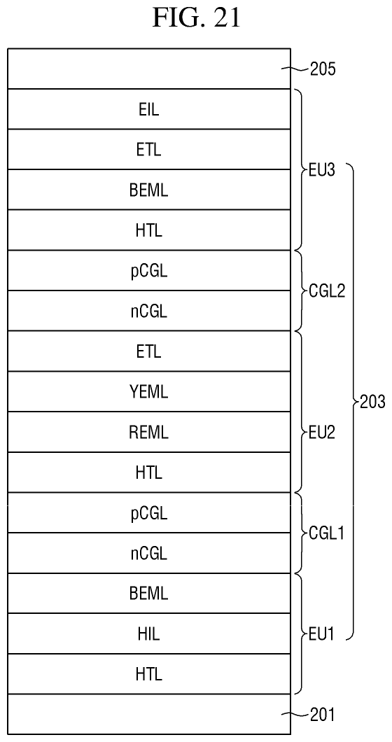

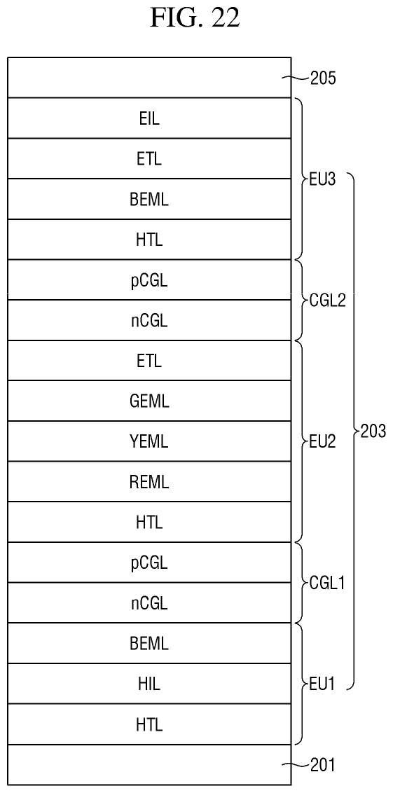

FIG. 21 is a cross-sectional view showing an example of the organic light-emitting diode of FIG. 19. FIG. 22 is a cross-sectional view showing an example of the organic light-emitting diode of FIG. 20.

Referring to FIG. 21, the light-emitting element, e.g., an organic light-emitting diode, may include a first light-emitting unit EU1, a second light-emitting unit EU2, and a third light-emitting unit EU3 stacked on one another in this order. The first charge generation layer CGL1 may be disposed between the first light-emitting unit EU1 and the second light-emitting unit EU2, and the second charge generation layer CGL2 may be disposed between the second light-emitting unit EU2 and the third light-emitting unit EU3. Each of the first charge generation layer CGL1 and the second charge generation layer CGL2 may include a negative charge generation layer nCGL and a positive charge generation layer pCGL.

The first light-emitting unit EU1 may include a blue emissive layer BEML. The first light-emitting unit EU1 may further include a hole injection layer HIL and a hole transport layer HTL between the pixel electrode 201 and the blue emissive layer BEML. According to an embodiment, a p-doped layer may be further included between the hole injection layer HIL and the hole transport layer HTL. The p-doped layer may be formed by doping the hole injection layer HIL with a p-type doping material. According to an embodiment, at least one of a blue light auxiliary layer, an electron blocking layer and a buffer layer may be further included between the blue emissive layer BEML and the hole transport layer HTL. The blue light auxiliary layer can increase the emission efficiency of the blue emissive layer BEML. The blue light auxiliary layer can increase the emission efficiency of the blue emissive layer BEML by adjusting the hole charge balance. The electron blocking layer may be used to prevent injection of electrons into the hole transport layer HTL. The buffer layer may be used to compensate for a resonance distance according to a wavelength of light emitted from the emissive layer.

The second light-emitting unit EU2 may include a yellow emissive layer YEML and a red emissive layer REML directly in contact with the yellow emissive layer YEML under the yellow emissive layer YEML. The second light-emitting unit EU2 may further include a hole transport layer HTL between the positive charge generation layer pCGL of the first charge generation layer CGL1 and the red emissive layer REML, and an electron transport layer ETL between the yellow emissive layer YEML and the negative charge generation layer nCGL of the second charge generation layer CGL2.

The third light-emitting unit EU3 may include a blue emissive layer BEML. The third light-emitting unit EU3 may further include a hole transport layer HTL between the positive charge generation layer pCGL of the second charge generation layer CGL2 and the blue emissive layer BEML. The third light-emitting unit EU3 may further include an electron transport layer ETL and an electron injection layer EIL between the blue emissive layer BEML and the common electrode 205. The electron transport layer ETL may be made up of a single layer or multiple layers. According to an embodiment, at least one of the blue light auxiliary layer, the electron blocking layer and the buffer layer may be further included between the blue emissive layer BEML and the hole transport layer HTL. At least one of the hole blocking layer and the buffer layer may be further included between the blue emissive layer BEML and the electron transport layer ETL. The hole blocking layer may be used to prevent injection of holes into the electron transport layer ETL.

The light-emitting element, e.g., organic light-emitting diode, shown in FIG. 22 is substantially identical to the light-emitting element, e.g., organic light-emitting diode, shown in FIG. 21 except for a stack structure of a second light-emitting unit EU2. Referring to FIG. 22, the second light-emitting unit EU2 may include a yellow emissive layer YEML, a red emissive layer REML directly in contact with the yellow emissive layer YEML under the yellow emissive layer YEML, and a green emissive layer GEML directly in contact with the yellow emissive layer YEML on the yellow emissive layer YEML. The second light-emitting unit EU2 may further include a hole transport layer HTL between the positive charge generation layer pCGL of the first charge generation layer CGL1 and the red emissive layer REML, and an electron transport layer ETL between the green emissive layer GEML and the negative charge generation layer nCGL of the second charge generation layer CGL2.

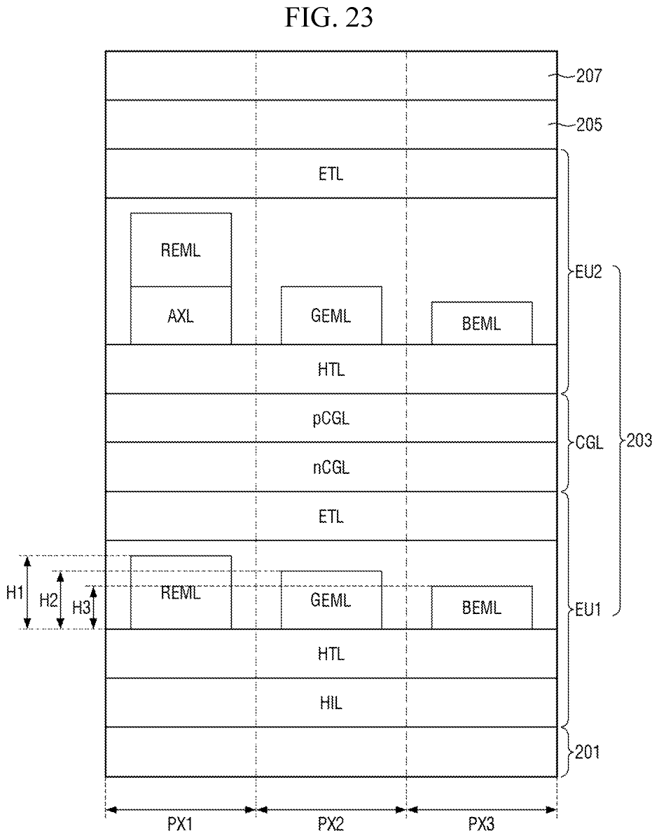

FIG. 23 is a cross-sectional view showing a structure of a pixel of a display device according to an embodiment of the present disclosure.

Referring to FIG. 23, a display panel of a display device may include a plurality of pixels, e.g., the above-described sub-pixels. The plurality of pixels may include a first pixel PX1, a second pixel PX2 and a third pixel PX3. Each of the first pixel PX1, the second pixel PX2 and the third pixel PX3 may include a pixel electrode 201, a common electrode 205 and an intermediate layer 203. According to an embodiment, the first pixels PX1 may be red pixels, the second pixels PX2 may be green pixels, and the third color pixels PX3 may be blue pixels.

The pixel electrode 201 may be independently disposed in each of the first pixel PX1, the second pixel PX2 and the third pixel PX3.

The intermediate layer 203 of each of the first pixel PX1, the second pixel PX2 and the third pixel PX3 may include a first light-emitting unit EU1, a second light-emitting unit EU2, and a charge generation layer CGL between the first light-emitting unit EU1 and the second light-emitting unit EU2, which are stacked on one another in this order. The charge generation layer CGL may include a negative charge generation layer nCGL and a positive charge generation layer pCGL. The charge generation layer CGL may be a common layer continuously formed across the first pixel PX1, the second pixel PX2 and the third pixel PX3.

The first light-emitting unit EU1 of the first pixel PX1 may include a hole injection layer HIL, a hole transport layer HTL, a red emissive layer REML, and an electron transport layer ETL sequentially stacked on the pixel electrode 201. The first light-emitting unit EU1 of the second pixel PX2 may include a hole injection layer HIL, a hole transport layer HTL, a green emissive layer GEML, and an electron transport layer ETL sequentially stacked on the pixel electrode 201. The first light-emitting unit EU1 of the third pixel PX3 may include a hole injection layer HIL, a hole transport layer HTL, a blue emissive layer BEML, and an electron transport layer ETL sequentially stacked on the pixel electrode 201. Each of the hole injection layer HIL, the hole transport layer HTL and the electron transport layer ETL of the first light-emitting units EU1 may be a common layer extended across the first pixel PX1, the second pixel PX2 and the third pixel PX3.

The second light-emitting unit EU2 of the first pixel PX1 may include a hole transport layer HTL, an auxiliary layer AXL, a red emissive layer REML, and an electron transport layer ETL sequentially stacked on the charge generation layer CGL. The second light-emitting unit EU2 of the second pixel PX2 may include a hole transport layer HTL, a green emissive layer GEML, and an electron transport layer ETL sequentially stacked on the charge generation layer CGL. The second light-emitting unit EU2 of the third pixel PX3 may include a hole transport layer HTL, a blue emissive layer BEML, and an electron transport layer ETL sequentially stacked on the charge generation layer CGL. Each of the hole transport layer HTL and the electron transport layer ETL of the second light-emitting units EU2 may be a common layer extended across the first pixel PX1, the second pixel PX2 and the third pixel PX3. According to an embodiment, at least one of a hole blocking layer and a buffer layer between the emissive layer and the electron transport layer ETL in the second light-emitting units EU2 of the first pixel PX1, the second pixel PX2 and the third pixel PX3.

A thickness H1 of the red emissive layer REML, a thickness H2 of the green emissive layer GEML, and a thickness H3 of the blue emissive layer BEML may be determined depending on the resonance distance. The auxiliary layer AXL may be additionally disposed to adjust the resonance distance and may include a material for adjusting resonance. For example, the auxiliary layer AXL may include the same material as the hole transport layer HTL.

Although the auxiliary layer AXL is disposed only in the first pixel PX1 in the example shown in FIG. 23, the embodiments of the present disclosure are not limited thereto. For example, the auxiliary layer AXL may be disposed in at least one of the first pixel PX1, the second pixel PX2 and the third pixel PX3 in order to match the resonance distance of each of the first pixel PX1, the second pixel PX2 and the third pixel PX3.

The display panel of the display device may further include a capping layer 207 disposed outside the common electrode 205. The capping layer 207 may be used to improve the emission efficiency by the principle of constructive interference. Accordingly, the out-coupling efficiency of the light-emitting element, e.g., organic light-emitting diode, can be increased, and thus the emission efficiency of the light-emitting element, e.g., organic light-emitting diode, can be improved.

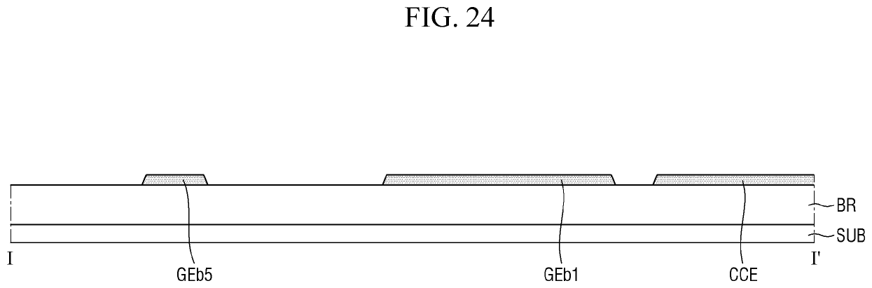

FIGS. 24 to 36 are cross-sectional views showing processing steps for illustrating a method of fabricating a display device according to an embodiment of the present disclosure.

Initially, as shown in FIG. 24, a barrier layer BR may be formed on a substrate SUB. For example, the barrier layer BR may be formed on the entire surface of the substrate SUB. Subsequently, a first conductive material layer may be formed on the entire surface of the substrate SUB including the barrier layer BR, and then the first conductive material layer may be patterned via a photolithography process and an etching process. As the first conductive material layer is patterned, the first conductive layer 111, e.g., see FIG. 7, for example, including the fifth counter gate electrode GEb5, the first counter gate electrode GEb1, and the capacitor electrode CCE may be formed on the barrier layer BR.

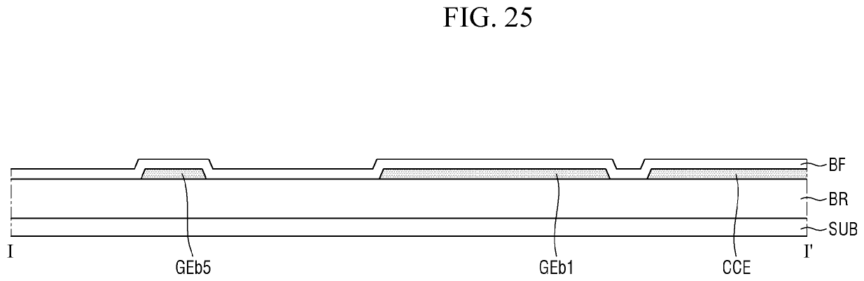

Subsequently, as shown in FIG. 25, a buffer layer BF may be formed on the entire surface of the substrate SUB including the first conductive layer 111. For example, the buffer layer BF may be formed on the entire surface of the substrate SUB including the fifth counter gate electrode GEb5, the first counter gate electrode GEb1, and the capacitor electrode CCE.

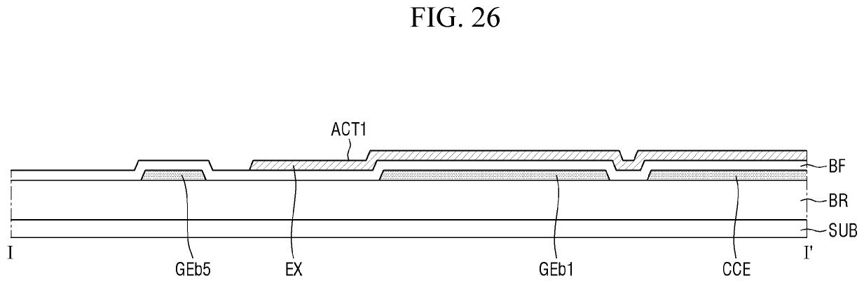

Subsequently, a first active material layer, for example, a first active material layer including indium-gallium-zinc-oxide (IGZO) may be formed on the entire surface of the substrate SUB including the buffer layer BF. Next, the first active material layer may be patterned via a photolithography process and an etching process. As the first active material layer is patterned, the second conductive layer 222, e.g., see FIG. 8, for example, as shown in FIG. 26, a first active layer ACT1 may be formed on the buffer layer BF.

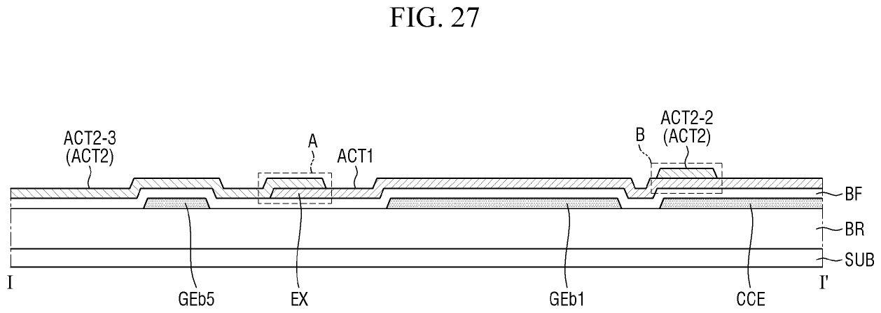

Subsequently, a second active material layer, for example, a second active material layer including indium-gallium-zinc-tin oxide (IGZTO) may be formed on the entire surface of the substrate SUB including the first active layer ACT1. Next, the second active material layer may be patterned via a photolithography process and an etching process. As the second active material layer is patterned, the third conductive layer 333, e.g., see FIG. 9, for example, as shown in FIG. 27, a second active layer ACT2 may be formed on the first active layer ACT1. For example, the second active layer ACT2 may include a second-first active layer ACT2-1, a second-second active layer ACT2-2, and a second-third active layer ACT2-3 as shown in FIG. 9. At this time, as shown in portion A of FIG. 27, at least a portion of the second active layer ACT2 may be in direct contact with at least a portion of the first active layer ACT1. For example, at least a portion of the second-third active layer ACT2-3 and at least a portion of the second-second active layer ACT2-2 may be formed directly on the first active layer ACT1 to be in direct contact with the first active layer ACT1. For example, as shown in portion A of FIG. 27, a portion of the second-third active layer ACT2-3 overlaps with the extension portion EX of the first active layer ACT1, and may be formed directly on the extension portion EX to be in direct contact with the extension portion EX. As another example, as shown in portion B of FIG. 27, a portion of the second-second active layer ACT2-2 overlaps with the first active layer ACT1, and may be formed directly on the first active layer ACT1 to be in direct contact with the first active layer ACT1. Accordingly, the conductive region of the second active layer ACT2 may be directly physically connected to the conductive region of the first active layer ACT1. Therefore, the second active layer ACT2 and the first active layer ACT1 may be electrically connected to each other without a contact hole.

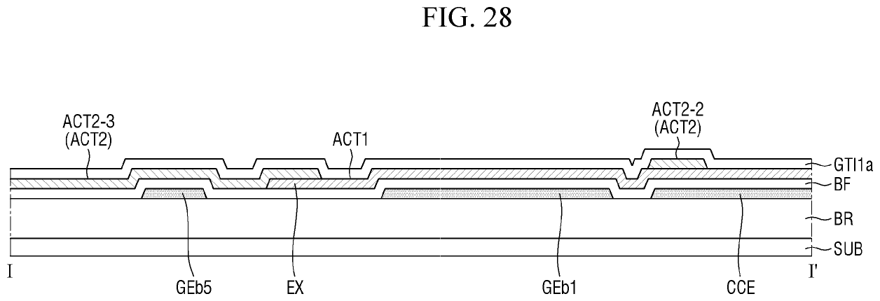

Subsequently, as shown in FIG. 28, a first insulating material layer GTI1a may be formed on the entire surface of the substrate SUB including the first active layer ACT1 and the second active layer ACT2.

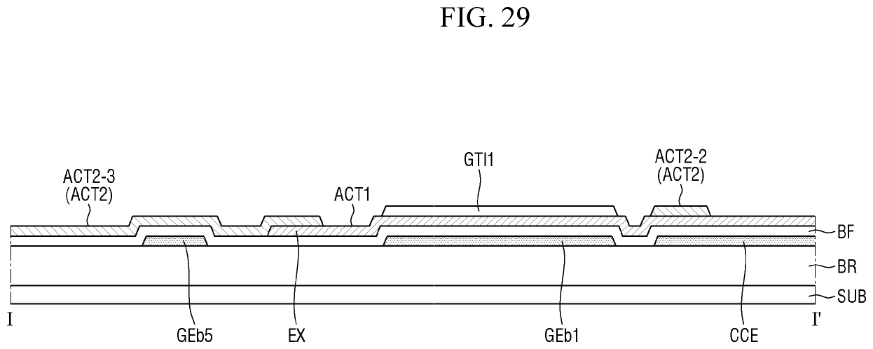

Subsequently, the first insulating material layer GTI1a may be patterned via a photolithography process and an etching process. As the first insulating material layer GTI1a is patterned, as shown in FIG. 29, a first gate insulating layer GTI1 may be formed on the first active layer ACT1. For example, the first gate insulating layer GTI1 may be disposed on the first active layer ACT1 to correspond to a first channel region CH1, e.g., see FIG. 8, of the first active layer ACT1.

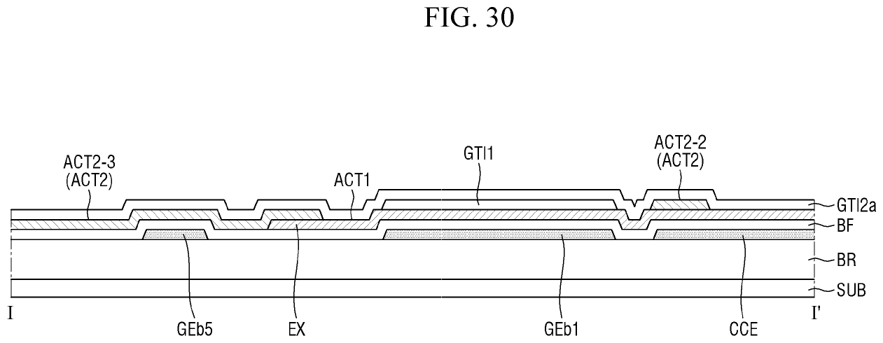

Subsequently, as shown in FIG. 30, a second insulating material layer GTI2a may be formed on the entire surface of the substrate SUB including the first active layer ACT1, the second active layer ACT2, and the first gate insulating layer GTI1.

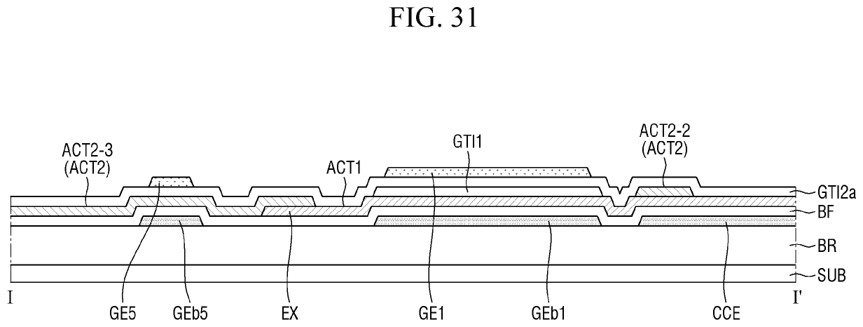

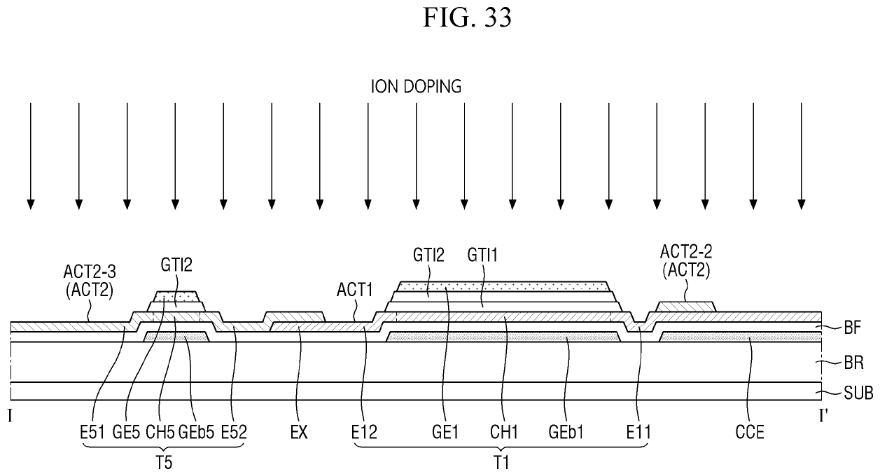

Subsequently, after a fourth conductive material layer is formed on the substrate SUB including the second insulating material layer GTI2a, the fourth conductive material layer may be patterned via a photolithography process and an etching process. As the fourth conductive material layer is patterned, as shown in FIG. 31, a fourth conductive layer 444, e.g., see FIG. 10, for example, including the fifth gate electrode GE5 and the first gate electrode GE1 may be formed on the second insulating material layer GTI2a. At this time, the fifth gate electrode GE5 may be formed on a second insulating material layer GTI2a to overlap the fifth channel region CH5, e.g., see FIG. 33, of the second-third active layer ACT2-3, and the first gate electrode GE1 may be formed on the second insulating material layer GTI2a to overlap the first channel region CH1, e.g., see FIG. 33, of the first active layer ACT1.

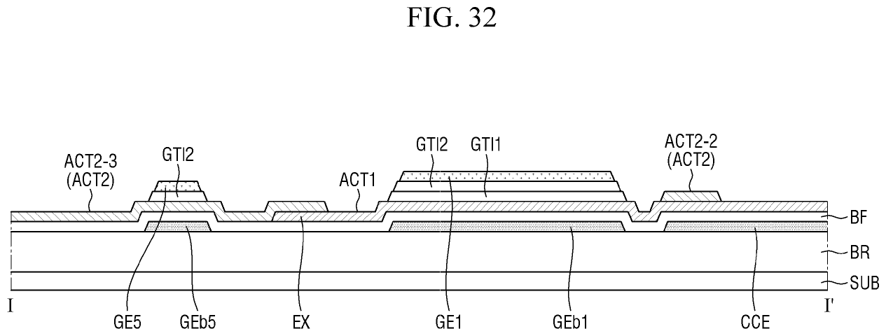

Next, an etching process may be performed using the fourth conductive layer 444, e.g., the fifth gate electrode GE5 and the first gate electrode GE1, as a mask, e.g., a hard mask. As the second insulating material layer GTI2a not covered by the fourth conductive layer 444 is removed by this etching process, the second gate insulating layer GTI2 shown in FIG. 32 may be formed. For example, the second gate insulating layer GTI2 may be disposed between the fifth gate electrode GE5 and the second-third active layer ACT2-3, and between the first gate electrode GE1 and first gate insulating layer GTI1.

Then, as shown in FIG. 33, ion, e.g., n+ ion, doping process may be performed using the fourth conductive layer 444, e.g., the fifth gate electrode GE5 and the first gate electrode GE1, as a mask. Channel regions may be formed in the first active layer ACT1 and the second active layer ACT2 through the ion doping process, and regions other than the channel regions may have conductivity. For example, ions may be implanted into regions of the first active layer ACT1 and the second active layer ACT2 that are not covered by the fourth conductive layer 444, and the region into which the ions are implanted may have conductivity. On the other hand, since ions are not implanted into a region of the first active layer ACT1 and the second active layer ACT2 covered by the fourth conductive layer 444, the region where the ions are not implanted may be defined as a channel region. As shown in FIG. 33, the first channel region CH1, the first electrode E51, and the second electrode E52 are formed in the second-third active layer ACT2-3, and the first channel region CH1, the first electrode E11, and the second electrode E12 may be formed on the first active layer ACT1.

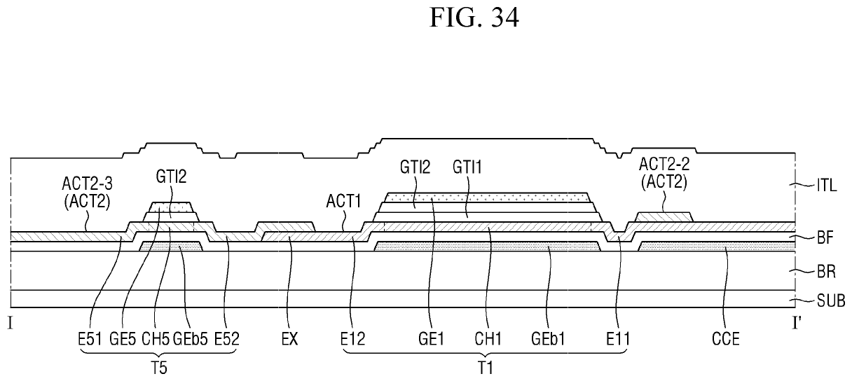

Subsequently, as shown in FIG. 34, an interlayer insulating layer ITL may be formed on the entire surface of the substrate SUB.

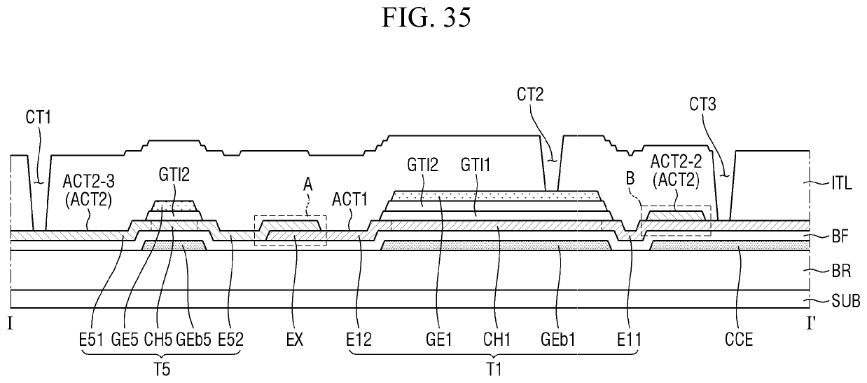

Subsequently, as shown in FIG. 35, a first contact hole CT1, a second contact hole CT2 and a third contact hole CT3 penetrating the interlayer insulating layer ITL may be formed via a photolithography process and an etching process. The first electrode E51 of the second-third active layer ACT2-3 may be exposed by the first contact hole CT1, the first gate electrode GE1 may be exposed by the second contact hole CT2, and the first electrode E11 of the first active layer ACT1 may be exposed by the third contact hole CT3.

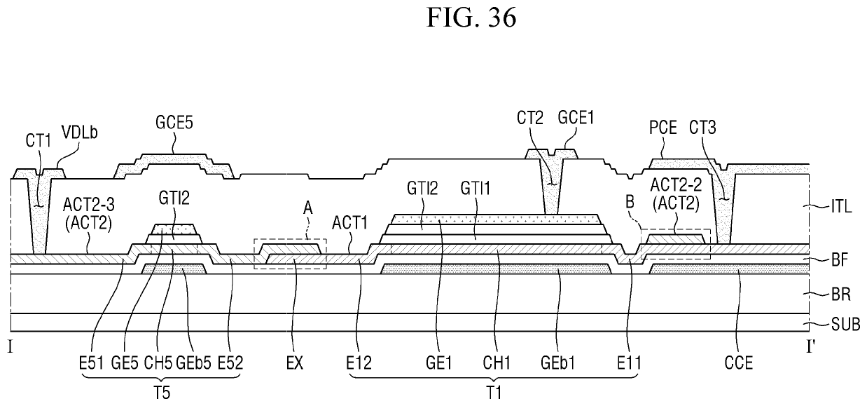

At this time, as shown in portion A of FIG. 35, since the second electrode E12 of the first active layer ACT1 is in direct contact with the second active layer ACT2, two contact holes for connecting the first active layer ACT1 and the second active layer ACT2 may not be formed. In addition, as shown in portion B of FIG. 35, since the first electrode E11 of the first active layer ACT1 is in direct contact with the second active layer ACT2, one contact hole for connecting the first electrode E11 of the first active layer ACT1 and the pixel connection electrode PCE, e.g., see FIG. 36, may not be formed. Accordingly, three contact holes for each pixel may be omitted.

Subsequently, after a fifth conductive material layer is formed on the entire surface of the substrate SUB including the interlayer insulating layer ITL, the fifth conductive material layer may be patterned via a photolithography process and an etching process. By patterning the fifth conductive material layer, the fifth conductive layer 555, e.g., see FIG. 11, for example, as shown in FIG. 36, including the first upper driving voltage line VDLb, the fifth gate connection electrode GCE5, the first gate connection electrode GCE1 and the pixel connection electrode PCE may be formed on the interlayer insulating layer ITL. At this time, the first upper driving voltage line VDLb may be connected to the first electrode E51 of the second-third active layer ACT2-3 through the first contact hole CT1, the first gate connection electrode GCE1 may be connected to the first gate electrode GE1 through the second contact hole CT2, and the pixel connection electrode PCE may be connected to the first electrode E11 of the first active layer ACT1 through the third contact hole CT3. Meanwhile, since the fifth conductive layer, e.g., the active connection electrode described above, does not need to be formed on the interlayer insulating layer ITL corresponding to the portion A of FIG. 36, an area of another line, e.g., the first upper driving voltage line VDLb or the upper reference voltage line VRLb, may be increased by using this area.

Subsequently, as shown in FIG. 14, the planarization layer VIA, the fourth contact hole CT4, the pixel electrode PE, the bank PDL, the spacer SPC, the light-emitting element LEL, and the encapsulation layer ENC may be sequentially formed on the fifth conductive layer 555 e.g., including the first upper driving voltage line VDLb, the fifth gate connection electrode GCE5, the first gate connection electrode GCE1, and the pixel connection electrode PCE.

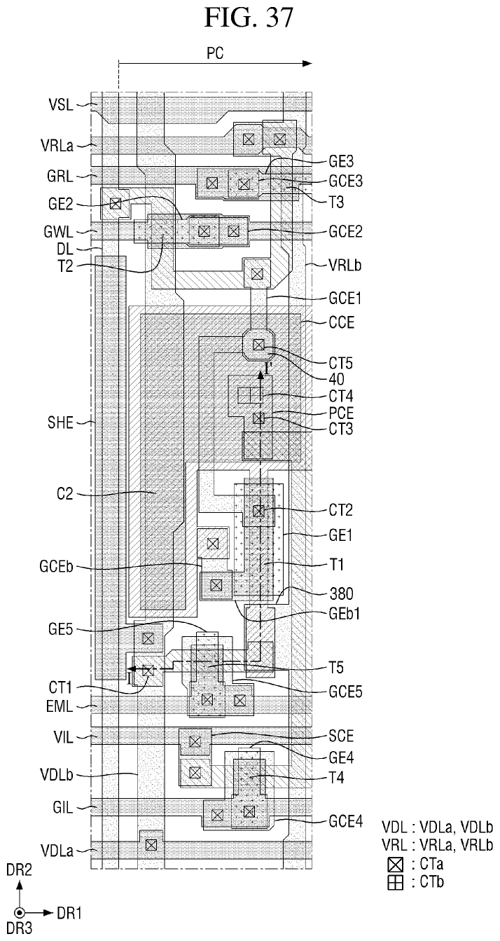

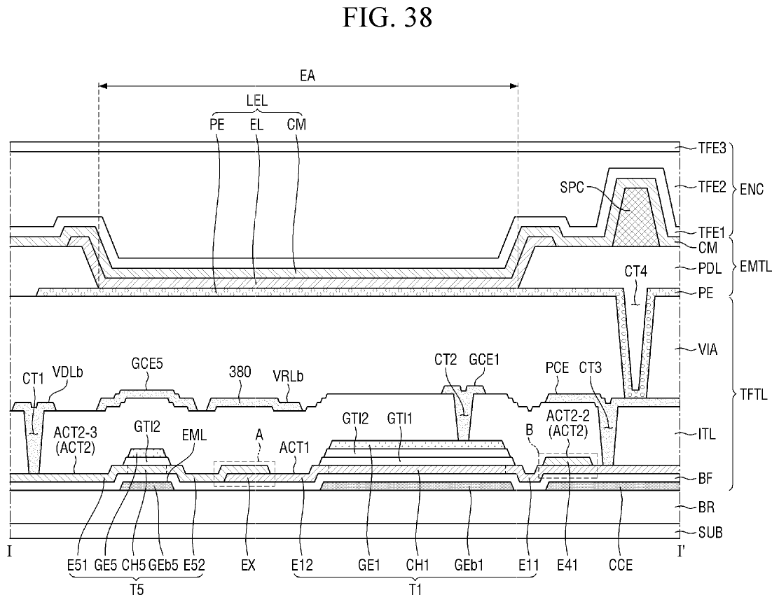

FIG. 37 is plan view of a pixel array of a display device including the pixel circuit PC of FIG. 5 according to one embodiment. FIG. 38 is a cross-sectional view taken along line I-I′ of FIG. 37.

The embodiments of FIGS. 37 and 38 are different from the embodiments of FIGS. 6 and 14 in that a portion of the upper reference voltage line VRLb is further extended in the direction opposite to the first direction DR1, e.g., first reverse direction, so that the upper reference voltage line VRLb overlaps a contact portion, e.g., portion A of FIG. 38, of the first active layer ACT1 and the second active layer ACT2, and the differences will be mainly described.

For example, as shown in FIGS. 37 and 38, the upper reference voltage line VRLb may further include an extension portion 380 extending in a first reverse direction. The extension portion 380 may be integrally formed with the upper reference voltage line VRLb. The extension portion 380 of the upper reference voltage line VRLb may be formed on the interlayer insulating layer ITL so as to overlap the contact portion, e.g., portion A, of the first active layer ACT1 and the second active layer ACT2. In other words, a reference voltage line VRLb may overlap the interface between the first active layer ACT1 and the second active layer ACT2 in the third direction DR3.

According to the present disclosure, since the first active layer ACT1 and the second active layer ACT2 are directly connected to each other, contact holes and active connection electrodes for connecting the first active layer ACT1 and the second active layer ACT2 may be omitted. Therefore, the upper reference voltage line VRLb may be further extended to the region in which the active connection electrodes are removed. Accordingly, the area of the upper reference voltage line VRLb may be increased, and thus the line resistance of the upper reference voltage line VRLb may be reduced.

Meanwhile, for example, a portion of the first upper driving voltage line VDLb instead of the upper reference voltage line VRLb may be further extended in the first direction DR1 to overlap the contact portion, e.g., portion A, of the first active layer ACT1 and the second active layer ACT2 described above. In other words, the first upper driving voltage line VDLb may overlap the interface between the first active layer ACT1 and the second active layer ACT2 in the third direction DR3.

In addition, the display device of the present disclosure may further include an upper initialization voltage line formed of, for example, the fifth conductive layer 555 and disposed along the second direction DR2. For example, the upper initialization voltage line may be connected to the initialization voltage line VIL through a contact hole of an insulating layer. At this time, the initialization voltage line VIL may be a lower initialization voltage line. In this case, instead of the aforementioned first upper driving voltage line and upper reference voltage line, the interlayer insulating layer ITL may be disposed so that at least a portion of the upper initialization voltage line overlaps the contact portion, e.g., portion A, of the first active layer ACT1 and the second active layer ACT2. In other words, the upper initialization voltage line may overlap the interface between the first active layer ACT1 and the second active layer ACT2 in the third direction DR3.

In concluding the detailed description, those skilled in the art will appreciate that many variations and modifications can be made to the embodiments without substantially departing from the principles of the inventive concept. Therefore, the disclosed embodiments of the invention are used in a generic and descriptive sense only and not for purposes of limitation.

What is claimed is:

1. A display device comprising:
a first active layer;
a first transistor connected to the first active layer;
a pixel electrode connected to the first transistor;
a second active layer including a material different from a material of the first active layer; and
a second transistor connected to the second active layer,
wherein at least a portion of the second active layer is directly connected to at least a portion of the first active layer.

2. The display device of claim 1,
wherein the first active layer and the second active layer are disposed on a same layer.

3. The display device of claim 1,
wherein the at least a portion of the second active layer is in direct contact with the at least a portion of the first active layer.

4. The display device of claim 1,
wherein the at least a portion of the second active layer is disposed on the first active layer.

5. The display device of claim 1,
wherein the at least a portion of the second active layer overlaps the first active layer.

6. The display device of claim 1,
wherein the first active layer includes an extension portion extending toward the second active layer, and
wherein the at least a portion of the second active layer is directly connected to the extension portion of the first active layer.

7. The display device of claim 1,
wherein an insulating layer is not disposed on an interface between the first active layer and the second active layer.

8. The display device of claim 1,
wherein the first active layer includes indium-gallium-zinc oxide.

9. The display device of claim 1,
wherein the second active layer includes indium-gallium-zinc-tin oxide.

10. The display device of claim 1,
wherein the first transistor is a driving transistor and the second transistor is a switching transistor.

11. The display device of claim 1,
further comprising a power line connected to the second transistor.

12. The display device of claim 11,
wherein the power line overlaps an interface between the first active layer and the second active layer.

13. The display device of claim 11,
wherein the power line is any one of a first driving voltage line, a reference voltage line and an initialization voltage line.

14. A display device comprising:
a first active layer;
a first transistor including a first gate electrode overlapping the first active layer;
a second active layer including a material different from a material of the first active layer;
a second transistor including a second gate electrode overlapping the second active layer; and
a pixel electrode connected to the first transistor,
wherein at least a portion of the second active layer is directly connected to at least a portion of the first active layer.

15. The display device of claim 14,
wherein the first active layer and the second active layer are disposed on a same layer.

16. The display device of claim 14,
wherein the at least a portion of the second active layer is in direct contact with the at least a portion of the first active layer.

17. The display device of claim 14,
wherein the at least a portion of the second active layer is disposed on the first active layer.

18. The display device of claim 14,
wherein the at least a portion of the second active layer overlaps the first active layer.

19. A method of fabricating a display device, the method comprising:
forming a first active layer on a substrate;
forming a second active layer including a material different from a material of the first active layer on the substrate, at least a portion of the second active layer being directly connected to at least a portion of the first active layer;
forming a first gate electrode of a first transistor on the first active layer; and
forming a second gate electrode of a second transistor on the second active layer.

20. The method of claim 19,
wherein the first active layer and the second active layer are disposed on a same layer.

21. The method of claim 19,
wherein the at least a portion of the second active layer is in direct contact with the at least a portion of the first active layer.
